(19) United States
(12) Patent Application Publication
(10) Pub. No.: US 2021/0122773 A1
(43) Pub. Date: Apr. 29, 2021

(54) HETEROATOMIC-BASED HOLE-TRANSPORT MATERIALS

(71) Applicant: Sigma-Aldrich Co. LLC, St. Louis, MO (US)

(72) Inventor: James Holst, St. Louis, MO (US)

(21) Appl. No.: 17/251,068

(22) PCT Filed: Jun. 11, 2019
(86) PCT No.: PCT/US2019/036537

§ 371 Date: Dec. 10, 2020

Related U.S. Application Data
(60) Provisional application No. 62/683,354, filed on Jun. 11, 2018.

(51) Int. Cl. C07F 9/54; C07F 7/08; C07F 9/6568; H01L 51/00

(52) U.S. Cl. CPC C07F 9/5442; C07F 7/081; C07F 9/65688; C07F 7/0838; H01L 51/0056; H01L 51/424; H01L 51/0055; H01L 51/0072; H01L 51/0074; H01L 51/006; H01L 51/0094; H01L 51/0073

(57) ABSTRACT

Heteroatomic hole transport materials are provided. The hole transport materials include a non-carbon core: two, four, or eight aromatic groups covalently bound to the non-carbon core; a. terminal substituted diphenylamine end unit on each aromatic group: and optionally aromatic linker groups linking the aromatic groups and the substituted diphenylamine end units. In some embodiments the non-carbon core is non-carbon central atom such as Si, Ge, B⁻, P⁺Sn or Pb. In other embodiments, the non-carbon core is a cubic silsesquioxane. Also provided are methods for making these materials. The materials are particularly useful as hole transport materials in perovskite solar cells.

### CROSS-REFERENCE TO RELATED APPLICATIONS

This application claims the benefit of priority of U.S. Provisional Patent Application No. 62/683,354 filed Jun. 11, 2018, the entirety of which is incorporated herein by reference.

### BACKGROUND

In recent years, perovskite solar cells have revolutionized the photovoltaic markets by reducing the processing costs associated with making solar cells without sacrificing performance. They have the potential to replace ubiquitous silicon-based technology. Organic-inorganic perovskites have proven to be very useful as light-harvesting materials due to the combination of their high light absorption coefficients, long diffusion length, direct band gap and high ambipolar mobility.

Typically perovskite solar cells are arranged in a planar heterojunction architecture, typically including five primary layers: a) a light-absorbing perovskite layer itself which is tasked with absorbing solar light, b) a hole (positive charge) transporting layer which transfers charge to c) a metal electrode (typically gold or silver). The electrons generated in the perovskite layer are transferred through d) a thin hole-blocking/electron-transporting layer to e) a transparent conducting electrode (such as fluorine-doped Tin Oxide (FTO)).

Current devices typically use 2,2′,7,7′-Tetrakis-(N,N-di-4-methoxyphenylamino)-9,9′-spirobiluorene, “Spiro-MeOTAD” (FIG. 2) as the hole-transport material. This material is quite expensive and labor intensive to make, requiring five steps. In addition, Spiro-MeOTAD also possesses poor hole-conductivity and requires a secondary cobalt-based dopant to improve upon its performance in devices, at the expense of device stability. Despite these drawbacks, Spiro-MeOTAD has very good film-formation properties and reasonable stability, making it the current hole-transport material of choice in perovskite solar cells.

Accordingly, as the demand for solar cells grows, a need exists for improved hole-transport materials. Such materials must retain good film-forming properties like Spiro-MeOTAD, but should improve also exhibit improved stability, particularly in UV light, and good power conversion efficiency; but also, when compared with current materials, the new materials should have improved hole-conductivity, reducing or even precluding the need for dopants. Additionally, new hole transport materials should have a more cost-effective, more efficient synthesis compared with current hole-transport materials, thus decreasing the overall cost of producing solar cells.

### SUMMARY OF THE INVENTION

Provided herein are new heteroatomic compounds. In one embodiment, a compound of Formula I is provided:

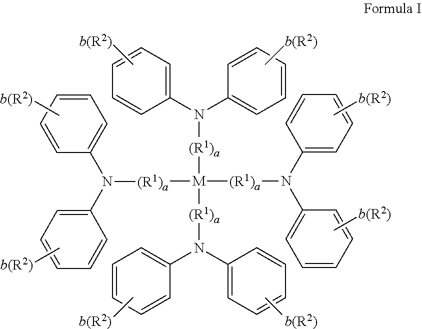

wherein: M is a metal selected from Si, Ge, B⁻ and P⁺, Sn and Pb; R¹ is an aryl group selected from arylene and heteroarylene, each R¹ is optionally substituted with one or more substituents R³, wherein R³ is selected from C₁ to C₈ alkyl, C₁ to C₈ alkoxy, aryl, alkylaryl and arylalkyl, or R³ is a bridging group that joins two adjacent R¹ groups to form a polycyclic aromatic group, and is selected from —(CR⁴R⁵)_{d}—, —O—, —SO₂— and —N(R⁶)—, wherein R⁴ and R⁵ are selected from H and C₁ to C₄ alkyl, d is 1 or 2, and R⁶ is selected methyl, ethyl, and phenyl; a is 1, 2 or 3; R² is selected from C₁ to C₈ alkoxy, CF₃, and N(R⁷)₂, wherein R⁷ is C₁ to C₄ alkyl; b represents 1, 2, 3 or 4 R² groups per phenyl ring; and when M is charged, the compound further includes a counterion, such as halide, bistriflimide, triflate, hexafluorophosphate; with the proviso that when M is Si, R¹ is phenylene, and b represents 1 R² group, then a is not 1 or 2.

In a second embodiment, a compound of Formula II is provided

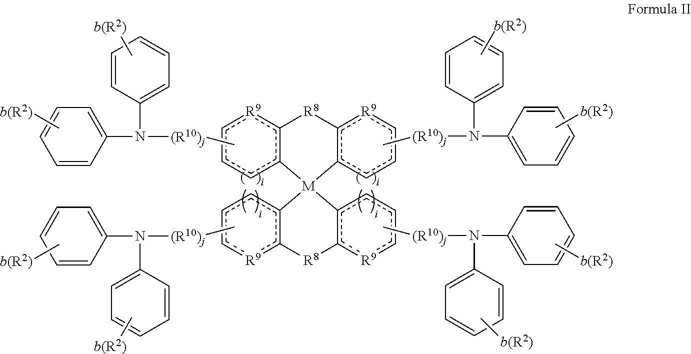

wherein M is selected from a metal, preferably, Si, Ge, B−, P+, Sn or Pb; R⁸ is selected from —(CR₄R₅)ₑ—, —S—, —O—, —SO₂— and N(R₆)—, wherein e is 0 or 1, R₄ and R₅ are selected from H and C₁ to C₄ alkyl, and R₆ is selected from methyl, ethyl, and phenyl; R₉ is selected from —CH— and —S—; i is 0 or 1; R₁₀ is selected from phenylene and thiophene; j is 0, 1 or 2; R2 is selected from C₁ to C₈ alkoxy, CF₃, and N(R₇)₂, wherein R₇ is C₁ to C₄ alkyl; b represents 1, 2, 3 or 4 substituents per ring; and when M is charged, the compound further includes a counterion.

Further provided is a compound of Formula III:

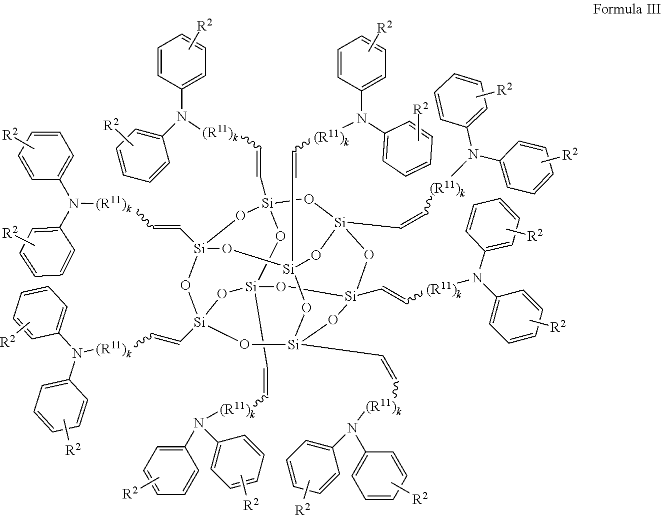

wherein [symbol] indicates that the bond can be cis or trans; R¹¹ is C₆ to C₁₃ arylene; k is 1 or 2; and R² is selected from C₁ to C₈ alkoxy, CF₃, and N(R⁷)₂, wherein R⁷ is C₁ to C₄ alkyl.

Also provided are uses of the compounds disclosed herein in devices, including perovskite solar cells, the device including a cathode, a hole transport layer, alight absorbing material, an electron transport layer and an anode, wherein the hole transport layer includes a compound selected from Formula I, Formula II, Formula III and combinations thereof.

### BRIEF DESCRIPTION OF THE DRAWINGS

FIG. 1 shows some representative compounds described herein.

FIG. 2 shows a three-step synthesis of a compound of Formula I.

FIG. 3 shows a three-step synthesis of second compound of Formula I.

FIG. 4 shows the five-step synthesis of Spiro-MeOTAD.

FIG. 5 shows a five-step synthesis of compounds of Formula IIa.

FIG. 6 shows a simplified three-step synthesis for the compounds of Formula IIa.

FIG. 7 shows an alternative four-step synthesis for the compounds of Formula IIa.

FIG. 8 shows the structure of an octakis(substituted) cubic silsesquioxane that forms the core of the compounds of Formula III.

FIG. 9 shows a synthesis of a compound of Formula III.

FIG. 10 shows an alternate synthesis of a compound of Formula III.

FIG. 11 illustrates the cuboid structure of hybrid halide perovskites of the type ABX₃; the organic or inorganic cations occupy position A (large light gray spheres), metals cations occupy position B (dark gray spheres), and halides occupy the X positions (black spheres).

FIG. 12 shows a schematic representation of a typical perovskite solar cell with layers (A) back contact/electrode, typically a metal such as Au or Ag; (B) hole transport layer, such as spiro-MeOTAD or a compound described herein; (C) perovskite layer; (D) electron transport or hole blocking layer; and (E) a transparent conducting electrode, such as fluorine-doped Tin Oxide (FTO).

FIG. 13 is a UV-Vis spectrum of an Si-spiro-MeOTAD analog thin film.

FIG. 14 is a UV-Vis spectrum of a P-spiro-MeOTAD bistriflimide thin film.

FIG. 15 is a cyclic voltammogram of P-spiro-MOTAD bistriflimide.

FIG. 16 is a square wave voltammogram of P-spiro-MOTAD bistriflimide.

### DETAILED DESCRIPTION OF THE INVENTION

Provided herein are new heteroatomic-based hole transport materials useful for opto-electronic devices and particularly useful as hole transport materials in, for example, perovskite solar cells, OLEDs, PLEDs, and other organic and printed electronics. These materials retain the beneficial film forming behavior of the conventional hole transport material, Spiro-MeOTAD, while improving the hole transporting characteristics.

The hole transport materials described herein include (a) a non-carbon core; (b) two, four, or eight aromatic groups covalently bound to the non-carbon core, (c) a terminal substituted diphenylamine end unit on each of the aromatic groups; and optionally (d) aromatic linker groups between the aromatic groups (b) and the substituted diphenylamine end units (c).

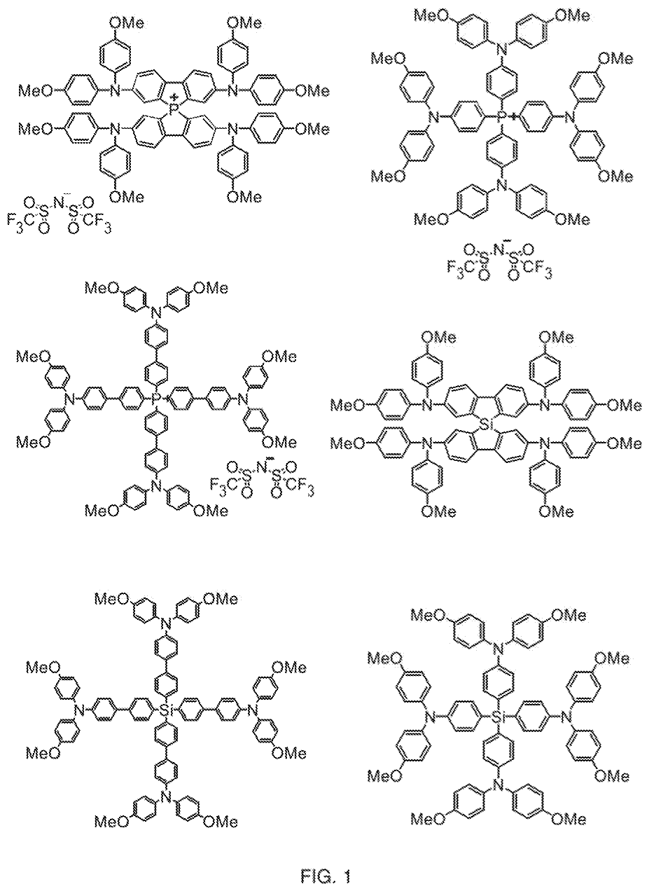

In some embodiments, the non-carbon core is a single center atom, having two or four aromatic groups generally arranged in a spiro or tetrahedral configuration around the center atom; each aromatic group having a terminal substituted diphenylamine end unit; and optionally aromatic linker groups are included between the aromatic groups (b) and the substituted diphenylamine end units (c). Some exemplary compounds are shown in FIG. 1. In these embodiments, the non-carbon central atom is chosen to provide improved hole-conductivity and can provide tenability, allowing the properties of the hole transport materials to be matched to particular perovskite layer, for example, in a perovskite solar cell application. It is believed that by using a non-carbon central atom such as Si, Ge, B⁻, P⁺, Sn or Pb, the hole conductivity can be improved without sacrificing film-forming capabilities. In some embodiments, incorporating specific non-carbon central atoms, particularly those with a charge and accompanied with a counterion, may reduce or eliminate the need to dopants when used in optoelectronic applications such as perovskite solar cells.

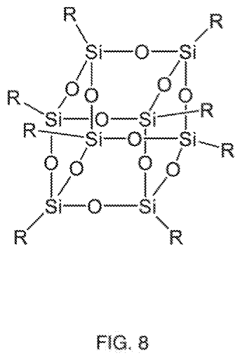

In another embodiment, rather than having a single metal atom as the core, an octakis substituted) cubic silsesquioxane is employed as the core. The cubic silsesquioxane core is shown in FIG. 8. In this embodiment, each Si atom in the cubic silsesquioxane includes an aryl group, linked to the Si atom through an alkenyl linker. Each aryl group has an additional terminal substituted diphenylamine end unit. Each of the embodiments is described in greater detail herein.

Additionally, provided herein are new methods of forming the hole transport materials described. These methods are advantageous over the current methods used to prepare spiro-MeOTAD as they have few steps, are less labor intensive, and require fewer reagents.

As used herein, the terms “core” or “central atom” are used interchangeably herein to refer to the atom or network of atoms at the center of each of compound. The compounds described herein have a non-carbon core. Preferred central atoms are typically post-transition metals, metalloids or non-metals. In some embodiments, the central atom has a positive charge or a negative charge, which is balanced out with one or more counterions. Preferred central atoms are chosen from Groups 13-15, including B⁻, Si, Ge, Sn, Pb and P⁺. In some embodiments, non-carbon Group 14 elements are preferred. In other embodiments, non-Group 14 atoms are preferred, namely P⁺ and B⁻, to alter the charge-transporting characteristics through the use of counterions needed to balance the overall charge on the material. This has been found to be beneficial for hole-transporting materials as it removes the need for doping the hole-transport material with a Co dopant. In still other embodiments, the core is an cubic silsesquioxane.

As used herein, the term “amino” refers to the —NH₂ radical; substituted or disubstituted amines refer to amino groups wherein one or both of the hydrogen atoms have been replaced with a different substituent, such as an aryl or substituted aryl.

The term “alkyl” refers to a straight or branched hydrocarbon chain radical consisting solely of carbon and hydrogen atoms, containing no unsaturation, having from one to eight carbon atoms (e.g., (C₁-C₈) alkyl). In other embodiments, an alkyl includes one to five carbon atoms (e.g., (C₁-C₅) alkyl). In other embodiments, an alkyl includes one to four carbon atoms (e.g., (C₁-C₄) alkyl). In other embodiments, an alkyl includes one to three carbon atoms (e.g., (C₁-C₃)alkyl). In other embodiments, an alkyl includes one to two carbon atoms (e.g., (C₁-C₂) alkyl). In other embodiments, an alkyl includes one carbon atom (e.g., (C₁) alkyl). Some exemplary alkyl groups are selected from methyl, ethyl, 1-propyl (n-propyl), 1-methylethyl (iso-propyl), 1-butyl, (n-butyl), 1-methylpropyl (sec-butyl), 2-methylpropyl (iso-butyl), 1,1-dimethylethyl (tert-butyl), 1-pentyl (n-pentyl). Alkyl groups attached to the rest of the molecule by a single bond. Unless stated otherwise specifically herein, alky; groups are optionally substituted by one or halo substituents. Some exemplary alkyl substituents used in the compounds described herein include methyl, ethyl and trifluoromethyl.

“Alkoxy” refers to a radical bonded through an oxygen atom of the formula —O-alkyl, where alkyl is an alkyl chain as defined above. Preferred alkoxy groups used herein include lower alkoxy groups, including methoxy, ethoxy and propoxy.

“Alkenyl” refers to a straight or branched hydrocarbon chain radical group consisting solely of carbon and hydrogen atoms, containing at least one carbon-carbon double bond. In certain embodiments, an alkenyl includes two to eight carbon atoms. In certain embodiments, an alkenyl includes two to six carbon atoms. In other embodiments, an alkenyl includes two to four carbon atoms. Some exemplary alkenyl groups include ethenyl (i.e., vinyl), prop-1-enyl (i.e., allyl), but-1-enyl, pent-1-enyl, penta-1,4-dienyl, and the like.

“Alkylene” or “alkylene chain” refers to a straight or branched divalent hydrocarbon chain linking the rest of the molecule to a radical group, consisting solely of carbon and hydrogen, containing no unsaturation and having from one to twelve carbon atoms, for example, methylene, ethylene, propylene, n-butylene, and the like. The alkylene chain is attached to the rest of the molecule through a single bond and to the radical group through a single bond. The points of attachment of the alkylene chain to the rest of the molecule and to the radical group are through one carbon in the alkylene chain or through any two carbons within the chain. In certain embodiments, an alkylene includes one to eight carbon atoms (e.g., (C₁-C₈) alkylene). In other embodiments, an alkylene includes one to five carbon atoms (e.g., (C₁-C₅) alkylene). In other embodiments, an alkylene includes one to four carbon atoms (e.g., (C₁-C₄) alkylene). In other embodiments, an alkylene includes one to three carbon atoms (e.g., (C₁-C₃) alkylene). In other embodiments, an alkylene includes one to two carbon atoms (e.g., (C₁-C₂) alkylene).

“Aryl” refers to a radical derived from an aromatic monocyclic or multicyclic hydrocarbon ring system by removing a hydrogen atom from a ring carbon atom. The aromatic monocyclic or multicyclic hydrocarbon ring system contains only hydrogen and carbon from five to eighteen carbon atoms (e.g., (C₅-C₁₈) aryl), where at least one of the rings in the ring system is fully unsaturated, i.e., it contains a cyclic, delocalized (4n+2) n-electron system. In certain embodiments, an aryl includes six to ten carbon atoms (e.g., (C₆-C₁₀) aryl). In certain embodiments, an aryl includes six carbon atoms (e.g., (C₆)aryl). The ring system from which aryl groups are derived include, but are not limited to, groups such as benzene, fluorene, indane, indene, tetralin and naphthalene. Unless stated otherwise specifically herein, the term “aryl” or the prefix “ar-” (such as in “aralkyl”) is meant to include aryl radicals optionally substituted by one or more substituents independently selected from alkyl, alkenyl, alkynyl, halo, fluoroalkyl and so forth.

“Arylene” refers to bivalent aromatic radicals having free valences at two positions on the aromatic ring. Some exemplary arylene groups include phenylene, which includes, e.g., o-phenylene, m-phenylene, and p-phenylene, or 1,2-phenylene, 1,3-phenylene, 1,4-phenylene; fluorenylidene, such as 2,7-fluorenylidene, naphthylene, and so forth, each of which may optionally be substituted at the other positions.

“Aralkyl” or “arylalkyl” refers to a radical of the formula —R-aryl where R is an alkylene chain as defined above, for example, methylene, ethylene, and the like. The alkylene chain part of the arylalkyl radical is optionally substituted as described above for an alkylene chain. The aryl part of the arylalkyl radical is optionally substituted as described above for an aryl group. In some embodiments, the arylalkyl is described as (C₆-C₁₀) aryl(C₁-C₈) alkyl where the (C₆-C₁₀) aryl and (C₁-C₈) alkyl are as defined above.

“Arylalkenyl” refers to a radical of the formula R-aryl where R is an alkenylene chain as defined above. The aryl part of the aralkenyl radical is optionally substituted as described above for an aryl group. The alkenylene chain part of the aralkenyl radical is optionally substituted as defined above for an alkenylene group.

“Halo” or “halogen” refers to fluoro, chloro, bromo or iodo substituents.

“Heterocyclyl” refers to a stable 3- to 18-membered non-aromatic ring radical that comprises two to twelve carbon atoms and from one to six heteroatoms selected from nitrogen, oxygen and sulfur. Unless stated otherwise specifically herein, the heterocyclyl radical is a monocyclic, bicyclic, tricyclic or tetracyclic ring system, which includes fused or bridged ring systems. The heteroatoms in the heterocyclyl radical are optionally oxidized. One or more nitrogen atoms, if present, are optionally quaternized. The heterocyclyl radical is partially or fully saturated. In some embodiments, the heterocyclyl is attached to the rest of the molecule through any atom of the ring(s).

“Heteroaryl” refers to a radical derived from a 3- to 18-membered aromatic ring radical that includes two to seventeen carbon atoms (e.g., (C₂-C₁₈) heteroaryl) and from one to six heteroatoms selected from nitrogen, oxygen and sulfur. As used herein, the heteroaryl radical is a monocyclic, bicyclic, tricyclic or tetracyclic ring system, wherein at least one of the rings in the ring system is fully unsaturated, i.e., it contains a cyclic, delocalized (4n+2)n-electron system. Heteroaryl includes fused or bridged ring systems. The heteroatom(s) in the heteroaryl radical is optionally oxidized. One or more nitrogen atoms, if present, are optionally quaternized. The heteroaryl is attached to the rest of the molecule through any atom of the ring(s). Unless stated otherwise specifically herein, the term “heteroaryl” is meant to include heteroaryl radicals as defined above which are optionally substituted by one or more substituents selected from alkyl, alkenyl, halo, fluoroalkyl, haloalkenyl, haloalkynyl, optionally substituted aryl, optionally substituted arylalkyl, optionally substituted arylalkenyl, optionally substituted heteroaryl, and so forth. Particularly preferred heteroaryl groups employed in the materials described herein are illustrated in greater detail below.

“Heteroarylalkyl” refers to a radical of the formula —R-heteroaryl, where R is an alkylene chain as defined above. If the heteroaryl is a nitrogen-containing heteroaryl, the heteroaryl is optionally attached to the alkyl radical at the nitrogen atom. The alkylene chain of the heteroarylalkyl radical is optionally substituted as defined above for an alkylene chain. The heteroaryl part of the heteroarylalkyl radical is optionally substituted as defined above for a heteroaryl group. In some embodiments, the heteroarylalkyl is described as (C₂-C₁₀) heteroaryl (C₁-C₈) alkyl where the (C₂-C₁₀) heteroaryl and (C₁-C₈) alkyl are as defined above.

In some embodiments, the compounds disclosed herein contain one or more asymmetric centers and thus give rise to enantiomers, diastereomers, and other stereoisomeric forms that are defined, in terms of absolute stereochemistry, as (R)- or (S)-. Unless stated otherwise, it is intended that all stereoisomeric forms of the compounds disclosed herein are contemplated. When the compounds described herein contain alkene double bonds, and unless specified otherwise, it is intended that these include both E and Z geometric isomers (e.g., cis or trans). Likewise, all possible isomers, as well as their racemic and optically pure forms, are also intended to be included. The term “geometric isomer” refers to E or Z geometric isomers (e.g., cis or trans) of an alkene double bond. The term “positional isomer” refers to structural isomers around a central ring, such as ortho-, meta-, and para-isomers around a benzene ring.

“Optional” or “optionally” means that a subsequently described event or circumstance may or may not occur and that the description includes instances when the event or circumstance occurs and instances in which it does not. For example, “optionally substituted aryl” means that the aryl radical is or is not substituted and that the description includes both substituted aryl radicals and aryl radicals having no substitution. “Optionally substituted” and “substituted or unsubstituted” are interchangeable.

Provided in a first embodiment are compounds of Formula I

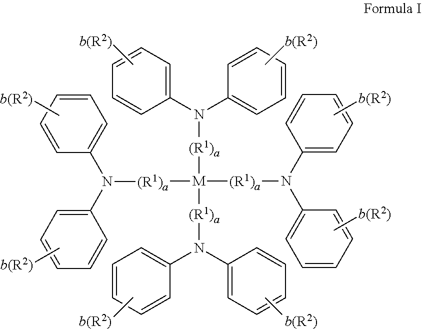

wherein M is selected from Si, Ge, B⁻ and P⁺, Sn and Pb. In a preferred embodiment, M is selected from Si, Ge, B⁻ and P⁺. In some embodiments, the preferred central atom, M is Si or P⁺. In other embodiments, non-Group 14 atoms are employed, namely P⁺ and B⁻, along with one or more counterions to balance the overall charge.

R¹ is selected from arylene and heteroarylene, each R¹ is optionally substituted with one or more substituents R³, wherein R³ is selected from C₁ to C₈ alkyl, C₁ to C₈ alkoxy, aryl, alkylaryl and arylalkyl, or R³ is a bridging group that joins two adjacent R¹ groups to form a polycyclic aromatic group, and is selected from —(CR⁴R⁵)_{d}—, —O—, —SO₂— and —N(R⁶)—, wherein R⁴ and R⁵ are selected from H and C₁ to C₄ alkyl, d is 1 or 2, and R⁶ is selected from alkyl and aryl. In a preferred embodiment, R⁶ is selected from methyl, ethyl, and phenyl. In a preferred embodiment, R is selected from phenylene and thiophene. In this embodiment, a may be 1, 2 or 3, and in preferred embodiments, a is 2 or 3.

In a preferred embodiment, two adjacent R¹ groups are joined by bridging group R³ to form a polycyclic aromatic group or polycyclic heteroaromatic group.

R² is selected from C₁ to C₈ alkoxy, CF₃, and N(R⁷)₂, wherein R⁷ is C₁ to C₄ alkyl; b represents 1, 2, 3 or 4 R² groups per phenyl ring. In some embodiments, R² is selected from C to C₄ alkoxy and b is 1 or 2. In some embodiments, b is 1 and R² is selected from para-methoxy and ortho-methoxy.

In embodiments wherein M is P⁺, the counterion to balance the overall charge may be selected from anions including, but not limited to halides, bistriflimide, triflate, hexafluorophosphate and combinations thereof. In embodiments wherein M is B⁻, preferred counterions are alkali metal cations, such as Li⁺, Na⁺ and K⁺.

Some exemplary embodiments include, but are not limited to the following:

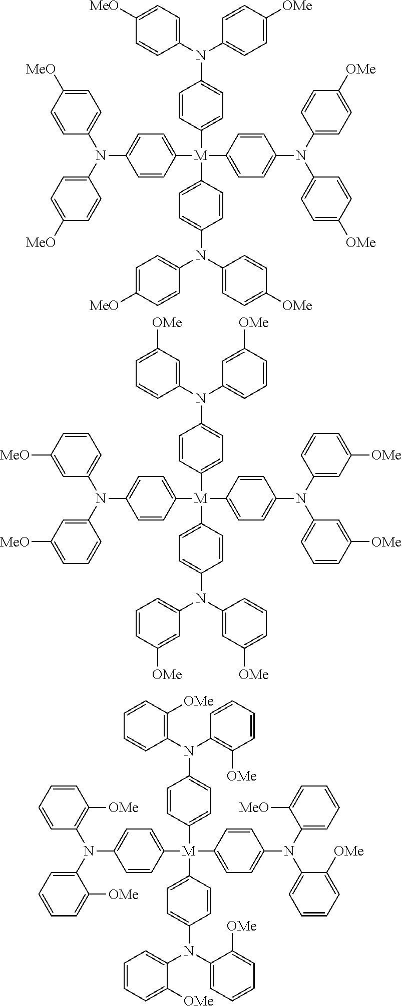

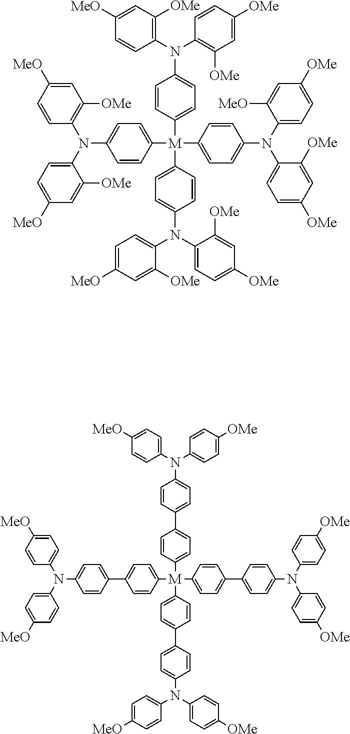

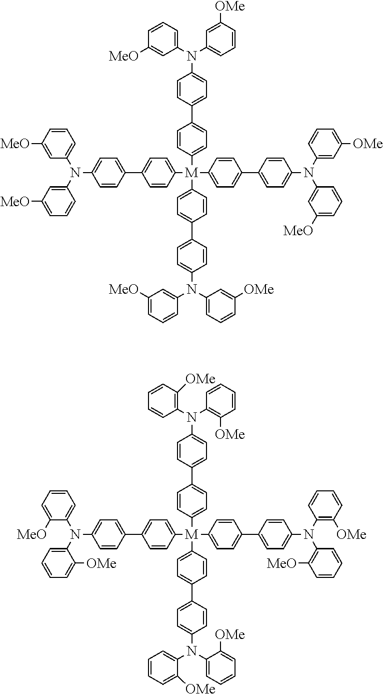

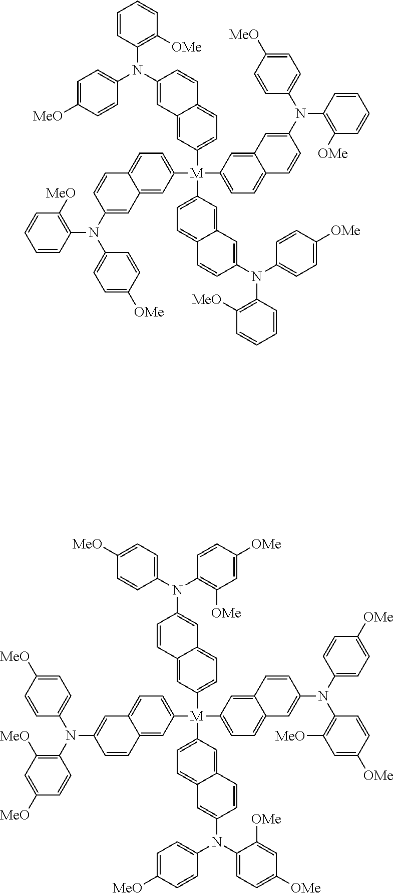

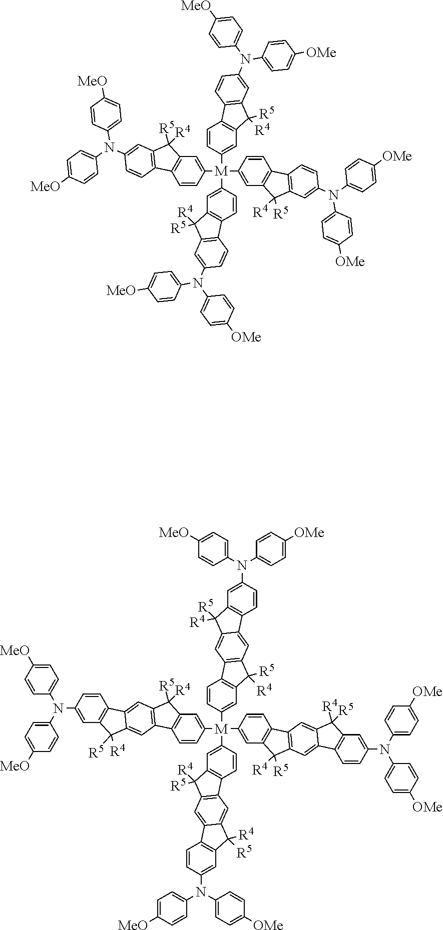

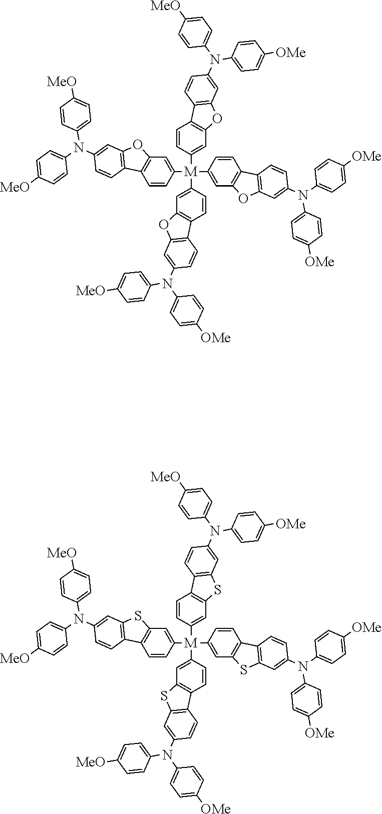

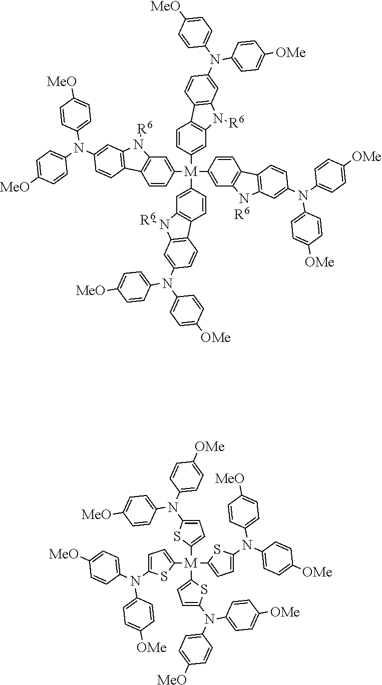

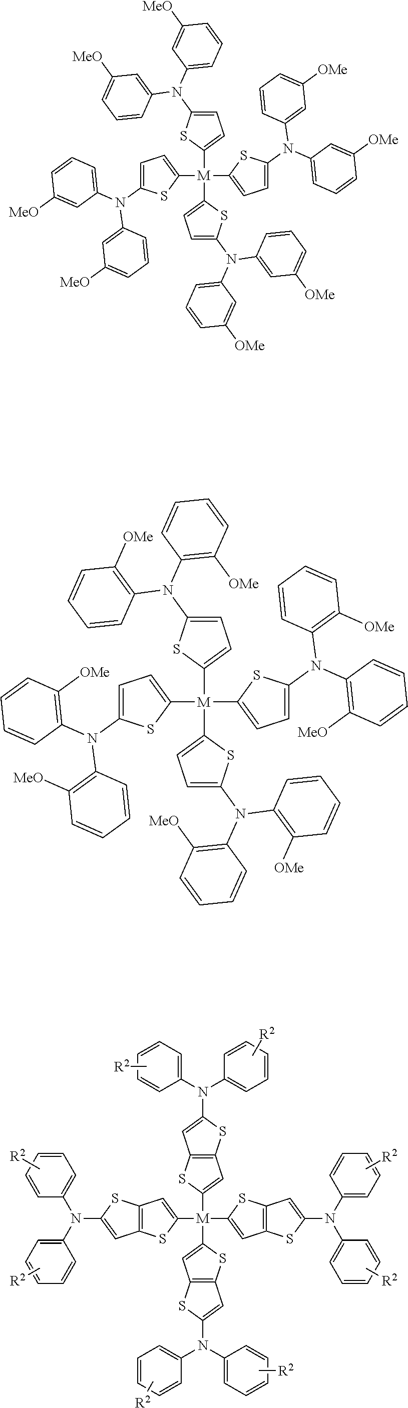

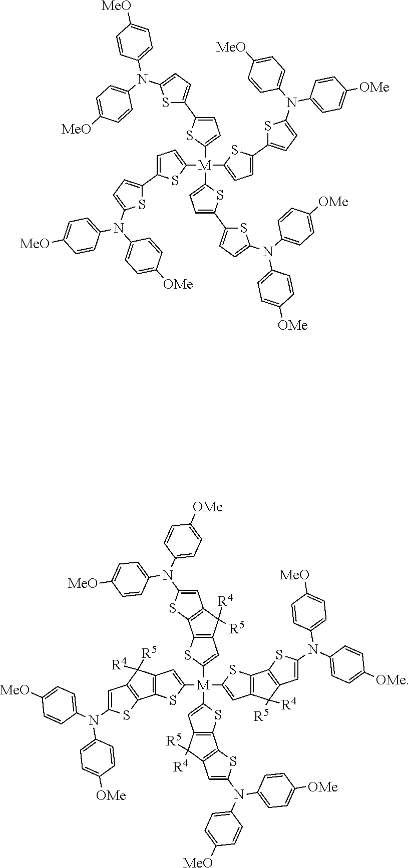

Some particularly preferred embodiments of Formula I include:

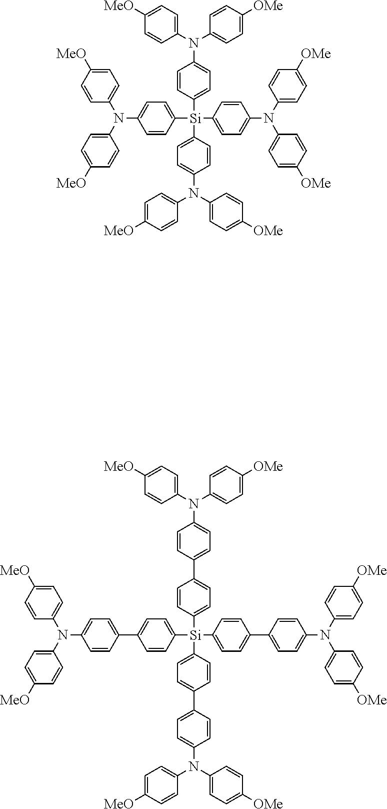 [SMILES: COc1ccc(N(c2ccc(OC)cc2)c2ccc([Si](c3ccc(N(c4ccc(OC)cc4)c4ccc(OC)cc4)cc3)(c3ccc(N(c4ccc(OC)cc4)c4ccc(OC)cc4)cc3)c3ccc(N(c4ccc(OC)cc4)c4ccc(OC)cc4)cc3)cc2)cc1 ; COc1ccc(N(c2ccc(OC)cc2)c2ccc(-c3ccc([Si](c4ccc(-c5ccc(N(c6ccc(OC)cc6)c6ccc(OC)cc6)cc5)cc4)(c4ccc(-c5ccc(N(c6ccc(OC)cc6)c6ccc(OC)cc6)cc5)cc4)c4ccc(-c5ccc(N(c6ccc(OC)cc6)c6ccc(OC)cc6)cc5)cc4)cc3)cc2)cc1]

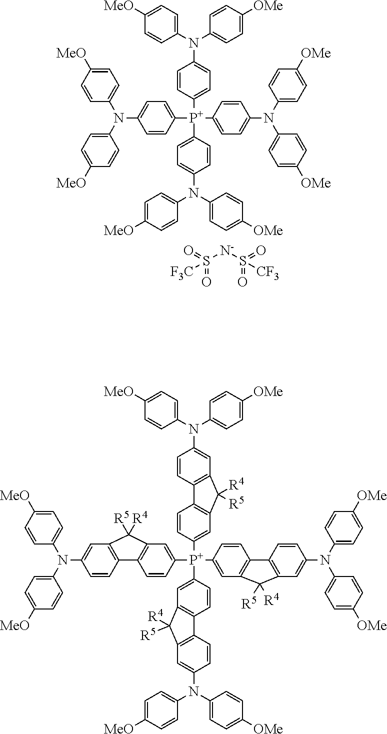

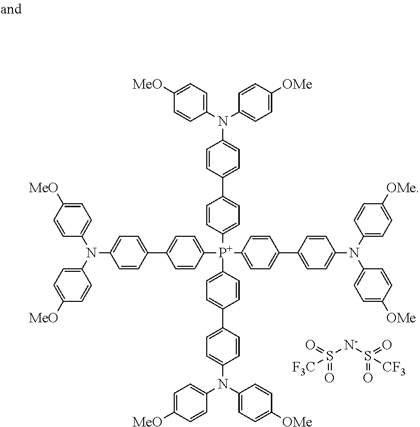 [SMILES: COc1ccc(N(c2ccc(OC)cc2)c2ccc(-c3ccc([P+](c4ccc(-c5ccc(N(c6ccc(OC)cc6)c6ccc(OC)cc6)cc5)cc4)(c4ccc(-c5ccc(N(c6ccc(OC)cc6)c6ccc(OC)cc6)cc5)cc4)c4ccc(-c5ccc(N(c6ccc(OC)cc6)c6ccc(OC)cc6)cc5)cc4)cc3)cc2)cc1 ; O=S(=O)([N-]S(=O)(=O)C(F)(F)F)C(F)(F)F]

Also provided herein are compounds of Formula II:

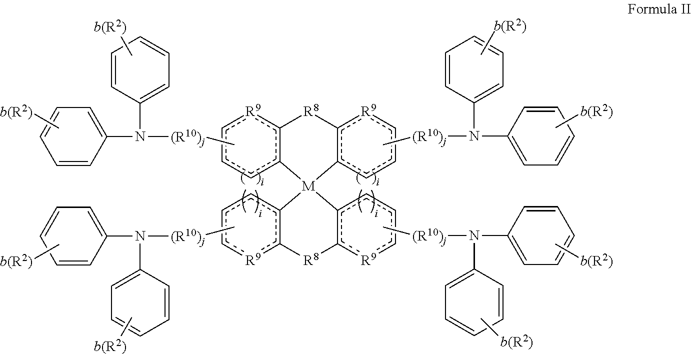

wherein M is selected from of Si, Ge, B⁻, P⁺, Sn and Pb. R⁸ is selected from —(CR⁴R⁵)ₑ—, —S—, —O—, —SO₂— and —N(R⁶)—, wherein e is 0 or 1, R⁴ and R⁵ are selected from H and C₁ to C₄ alkyl, and R⁶ is selected from alkyl and aryl, and in preferred embodiments is selected from methyl, ethyl, and phenyl. R⁹ is selected from —CH— and —S—; i is 0 or 1. R¹⁰ is selected from aryl and heteroaryl: in preferred embodiments, R¹⁰ is selected from phenylene and thiophene; j is 0, 1 or 2; R² is selected from C₁ to C₈ alkoxy, CF₃, and N(R⁷)₂, wherein R⁷ is C₁ to C₄ alkyl, and b represents 1, 2, 3 or 4 substituents per ring.

In embodiments when M is charged, the compound further includes a counterion. The counterions described above for Formula I are also suitable for the compounds of Formula II. When M is P⁺, the counterion to balance the overall charge may be selected from anions including, but not limited to halides, bistriflimide, triflate, hexafluorophosphate and combinations thereof. In embodiments in which M is B⁻, preferred counterions are alkali metal cations, such as Li⁺, Na⁺ and K⁺.

In some preferred embodiments of Formula II, the compounds are those of Formula IIa:

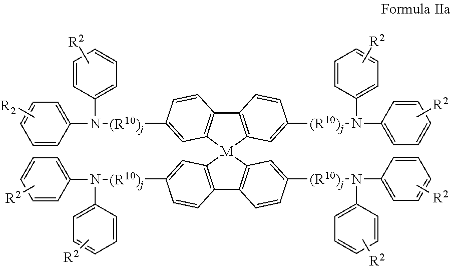

wherein M is selected from Si, Ge, B⁺ and P⁻, R¹⁰ is selected from phenylene and thiophene; j is 0, 1 or 2; R² is selected from C₁ to C₄ alkoxy; and when M is charged, the compound further includes a counterion as described above.

Some exemplary compounds of Formula IIa include:

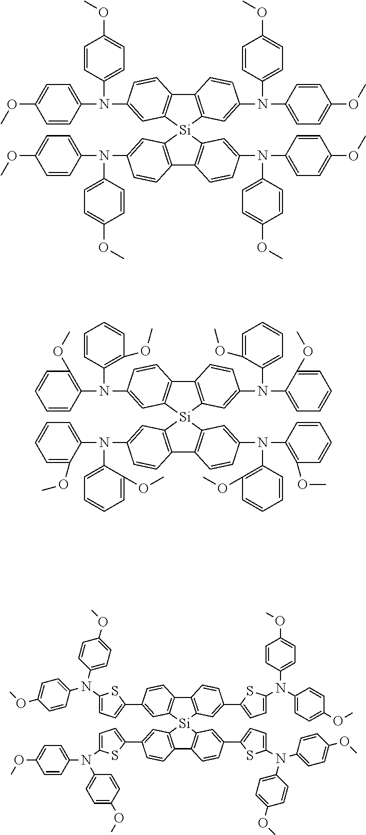

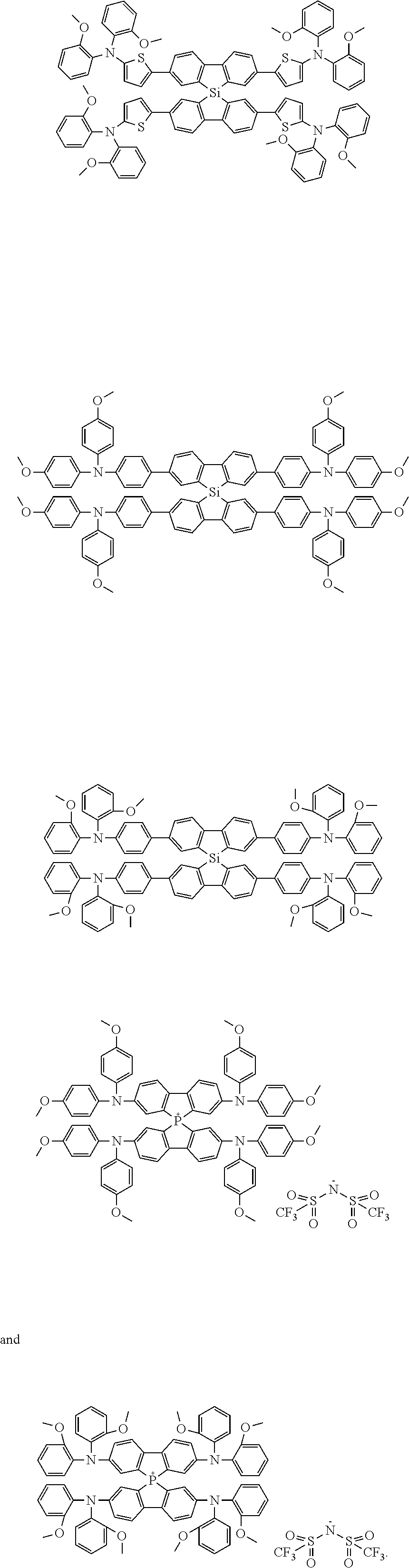

In other embodiments, preferred compounds of Formula II, include those of Formula IIb:

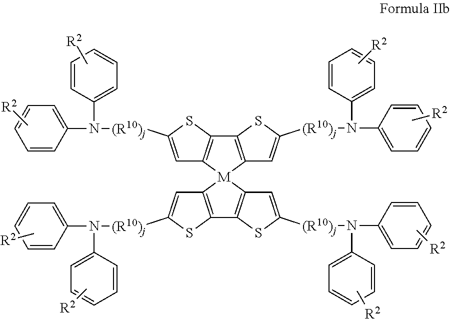

wherein M is selected from Si, Ge, B⁺ and P⁻, R¹⁰ is selected from phenylene and thiophene; j is 0, 1 or 2; R² is selected from C₁ to C₄ alkoxy; and when M is charged, the compound further includes a counterion as described above.

Some preferred compounds of Formula IIb include:

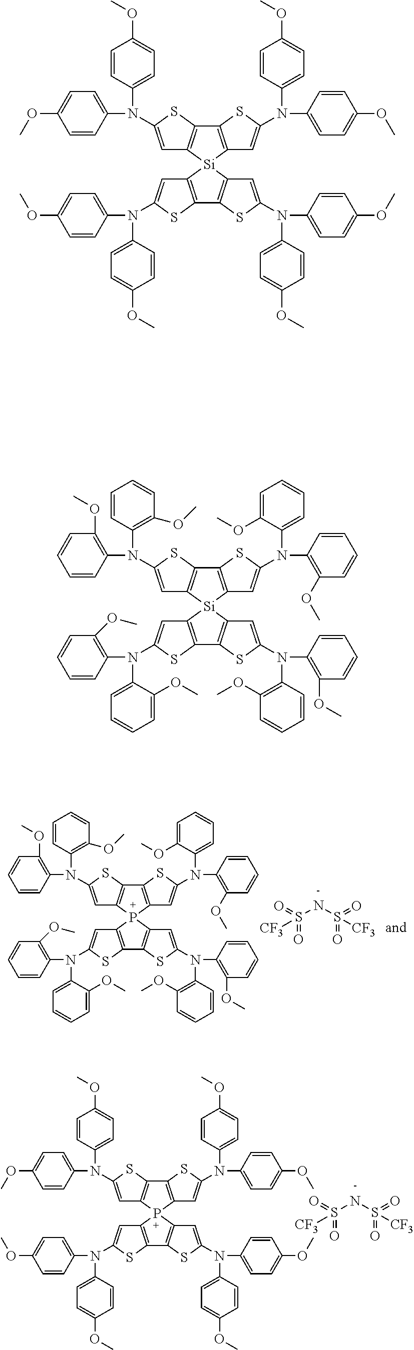

In still other embodiments, preferred compounds of Formula II, include those of Formula IIc:

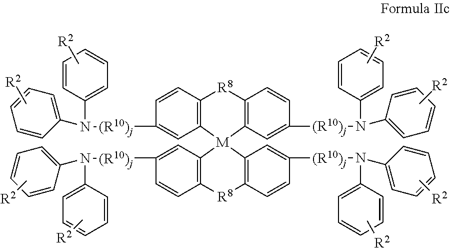

wherein M is selected from Si, Ge, B⁺ and P⁻; R⁸ is selected from —S—, —O—, —SO₂— and —N(R⁶)—, wherein R⁶ is selected from methyl, ethyl, and phenyl; R¹⁰ is selected from phenylene and thiophene; j is 0, 1 or 2; R² is selected from C₁ to C₄ alkoxy; and when M is charged, the compound further includes a counterion as described above.

Some preferred compounds of Formula IIc include:

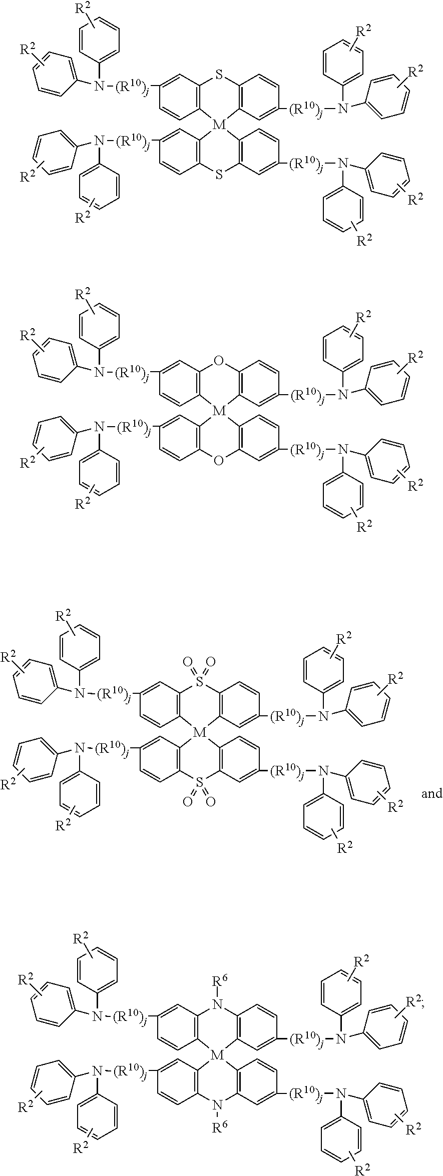

wherein M is selected from Si, Ge, B⁺ and P⁻; R² is selected from para-methoxy and ortho-methoxy; R⁶ is selected from methyl, ethyl, and phenyl; R¹⁰ is selected from phenylene and thiophene; j is 0 or 1; and when M is charged, the compound further includes a counterion.

Further provided are compounds of Formula III:

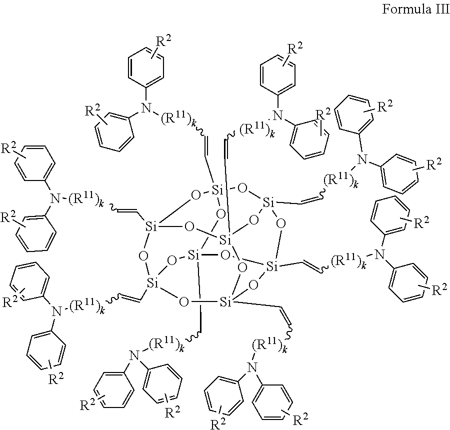

wherein [symbol] indicates that the bond can be cis or trans; R¹¹ is C₆ to C₁₃ arylene; k is 1 or 2; and R² is selected from C₁ to C₈ alkoxy, CF₃, and N(R⁷)₂, wherein R⁷ is C₁ to C₄ alkyl.

In some embodiments R¹¹ is selected from phenylene and fluorene. In a preferred embodiment of Formula III, R¹¹ is selected 1,4-phenylene and 2,7-9H-fluorene.

Additionally, new and simplified syntheses for the new hole transport materials are provided. Advantageously, these syntheses can be performed in as few as three steps, compared with five steps necessary to synthesize the conventional hole transport material, Spiro-MoOTAD. Reagents for the syntheses provided herein are available from commercial sources, such as Sigma-Aldrich (St. Louis, Mo.).

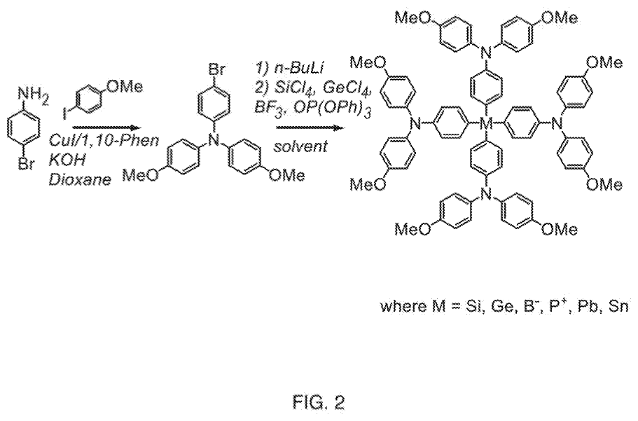

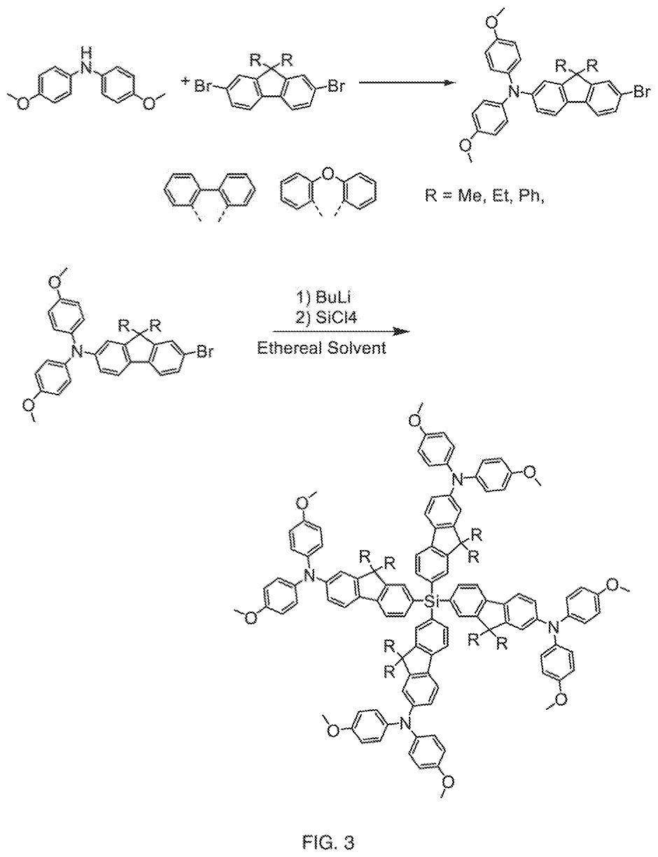

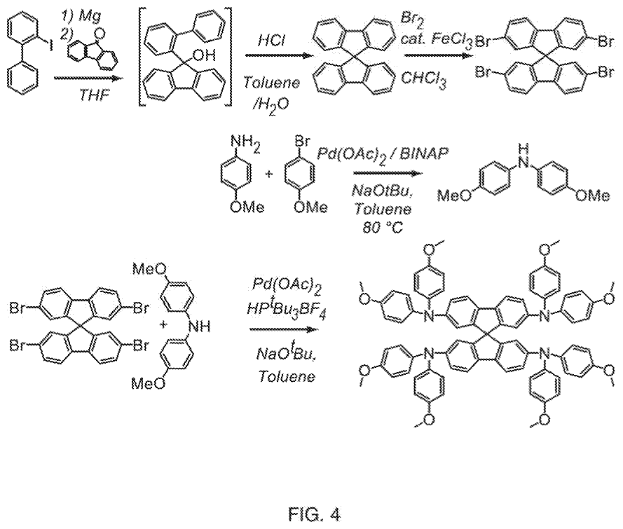

FIG. 2 shows a three-step synthesis of a tetrahedral hole transport material of Formula I provided herein. FIG. 3 shows a three-step synthesis for a second embodiment of tetrahedral hole transport materials described herein. In this embodiment, four optionally 9-substituted fluorenyl groups are covalently bound to the central atom and the terminal substituted diphenylamine end units at the 2- and 7-positions of the fluorenyl groups. For comparison. FIG. 4 shows the conventional five-step synthesis of spiro-MeOTAD.

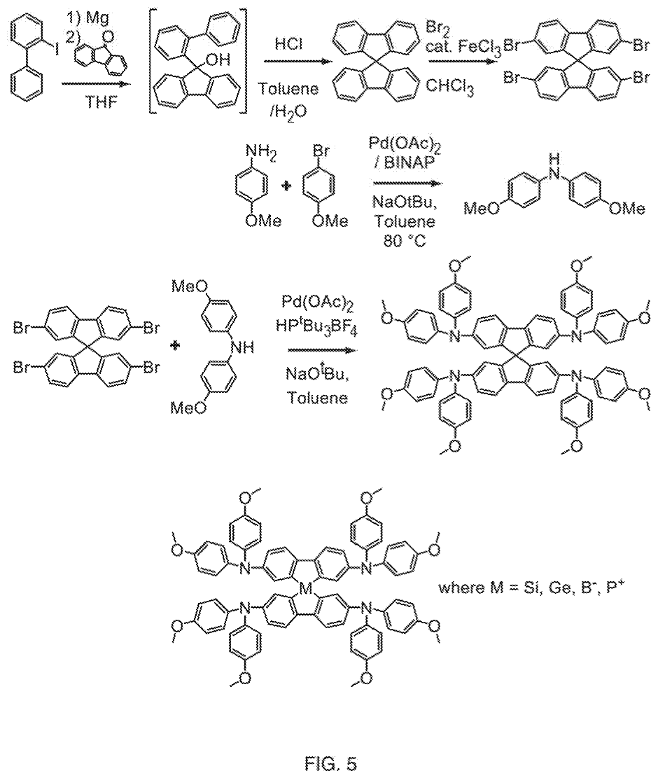

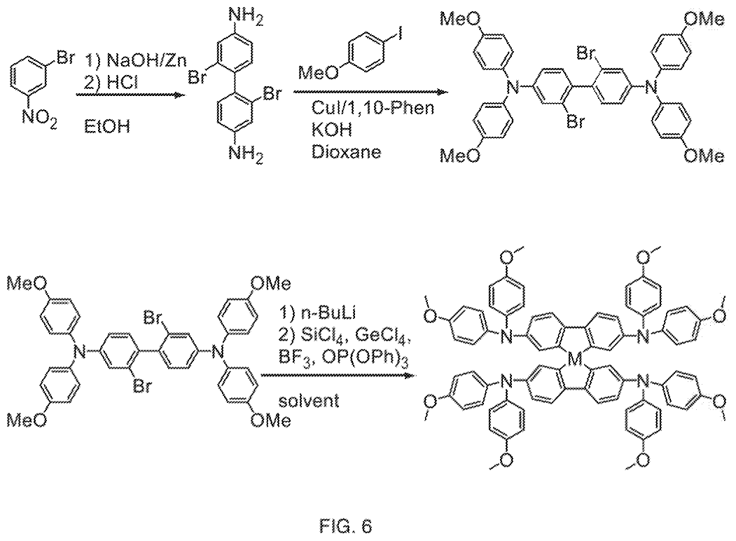

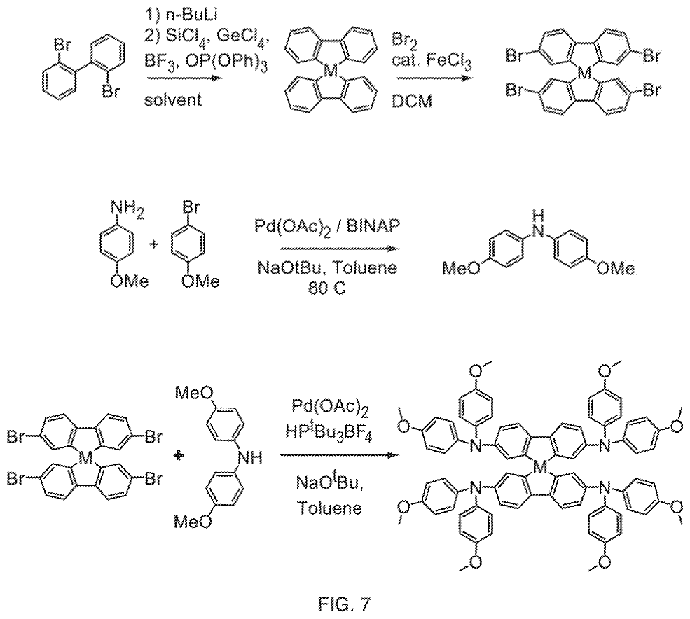

As illustrated in FIG. 5, a five-step synthesis, analogous to the synthesis of spiro-MeOTAD was first examined for the synthesis of the compounds of Formula II, which, like spiro-MeOTAD, have a 2,2,7,7-tetrakis substituted-9,9-spirobifluorene configuration around the central atom. Unlike spiro-MeOTAD, the central atom of Formula II is a non-carbon atom selected from Si, Ge, B⁻, P⁺, Sn or Pb. FIG. 6 shows a simplified three-step synthesis for the preparation of compounds of Formula IIa. FIG. 7 shows an alternate four-step synthesis for the preparation of compounds of Formula IIa.

The three-step synthesis shown in FIG. 6 is the preferred method for preparing the compounds of Formula II. Synthetically, there are fewer steps, and further, this method also provides a common intermediate which further reduces the number of reactions when making a broad range of materials.

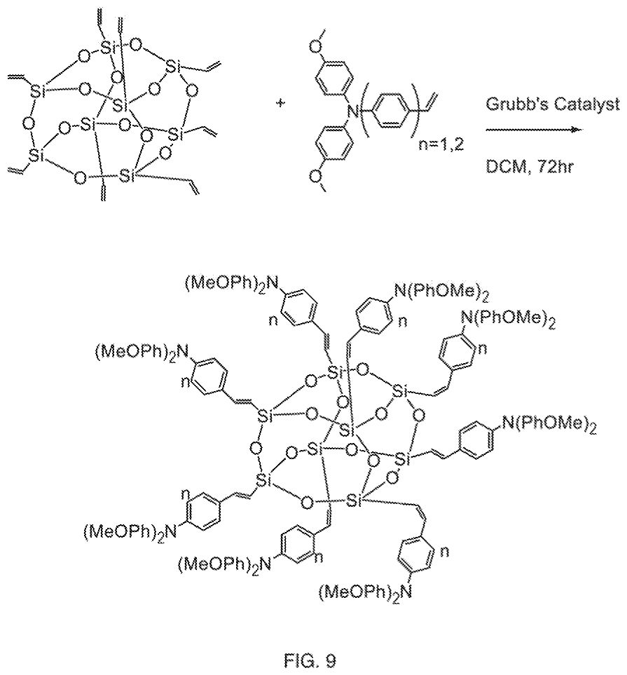

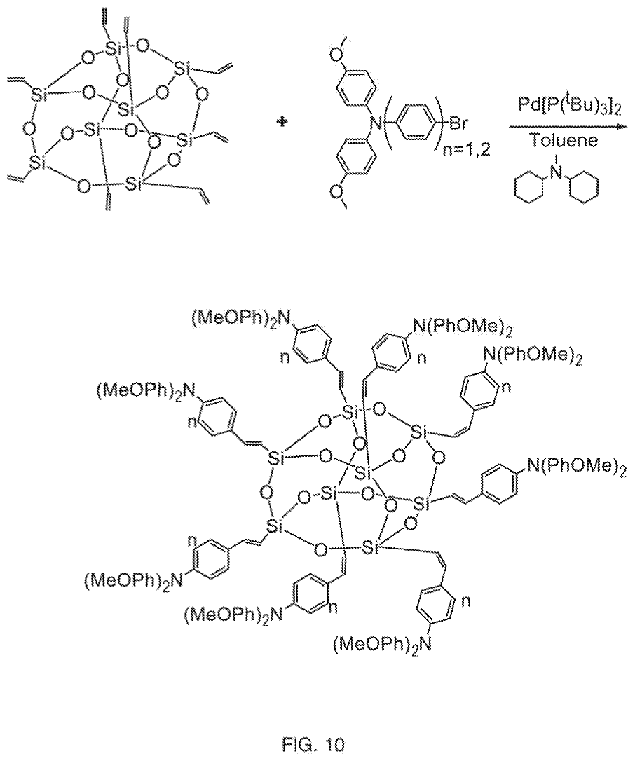

FIGS. 9 and 10 provide two methods for preparing the compounds of Formula III, which have a cubic silsesquioxane core.

The reduction in synthetic steps provided by the methods disclosed herein, reduces the overall synthesis cost thus further increasing the advantages of the materials provided herein over conventional materials.

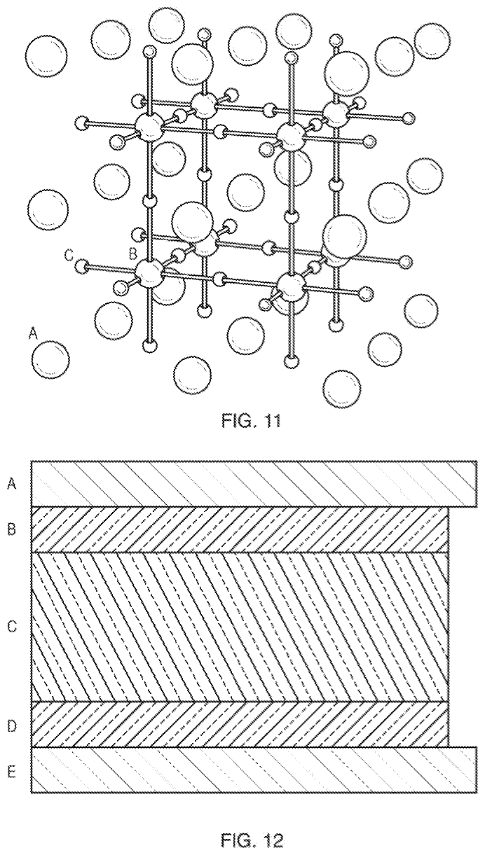

Use in Perovskite Solar Cells. The materials described herein have particular usefulness as hole transport materials in perovskite solar cells. Perovskites are a group of structurally related materials with the generic formula ABX₃, illustrated in FIG. 11, where A, B, and X represent an organic or inorganic cation, a metal cation, and a halide anion, respectively. Perovskites themselves have been known for over a century, and their semiconducting behavior has been known since the 1950s. More recent advances have expanded the usefulness of these materials, making them useful in broader applications. By varying the organic cations and/or the metal cations, the properties of the perovskites, including, e.g., optical absorption bandgap, are highly tunable. In recent years, these compounds have been used in the light absorbing layer of solar cells.

In 2009, the use of the pervoskite methylammonium-lead triiodide, CH3 NH₃PbI₃ was suggested as a photosensitizer for liquid electrode-based dye-sensitized solar cells. Soon thereafter, a solid-state version of perovskite solar cells, using CsSnIF, was reported. The configuration of the solid state perovskite solar cell, including spiro-MeOTAD as a hole transport material showed promise for the future of these devices, due to increased stability and solar power conversion efficiency (PCE).

FIG. 12 illustrates a typical arrangement for perovskite solar cells (PSCs). There are five primary layers: (A) an electrode, typically a thin film of Au or Ag serving as the back contact; (B) hole transport layer; (C) perovskite layer; (D) electron transport or hole blocking layer, and (E) a transparent conducting electrode, such as fluorine-doped tin oxide (FTO).

Prompt and quantitative capture of photogenerated charge carriers is essential to deliver maximum PCE. For the best performance, hole transport materials must meet several requirements. Along with the high hole mobility, these materials must have good compatibility between their HOMO energy levels and the valence band level of the perovskite. High hole mobility permits fast extraction of charges and a higher photocurrent. Sluggish movement of holes leads to higher internal resistance and this in turn reduces the fill factor of devices. In conventional PSCs, the hole transport layer is spiro-MOTAD, though as described above, spiro-MeOTAD is less than ideal, e.g., it is difficult and labor-intensive to synthesize, and it requires the use of a dopant to maximize PCE. The compounds described herein, have been developed to use in place spiro-MeOTAD to provide hole transport layers with improved properties while reducing or eliminating the need for dopants.

### EXAMPLES

The following hole transport materials were prepared using the following methods.

### Example 1

Synthesis of DPA-TPS, C₈₀H₇₂N₄O₈Si, MW 1245.54. A first tetrahedral hole transport material was prepared using the three-step synthesis described herein.

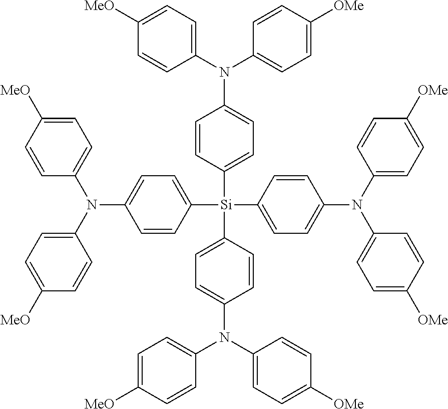 [SMILES: COc1ccc(N(c2ccc(OC)cc2)c2ccc([Si](c3ccc(N(c4ccc(OC)cc4)c4ccc(OC)cc4)cc3)(c3ccc(N(c4ccc(OC)cc4)c4ccc(OC)cc4)cc3)c3ccc(N(c4ccc(OC)cc4)c4ccc(OC)cc4)cc3)cc2)cc1]

A flask was charged with 3.0 g tetrakis(4-bromophenyl) silane, 5.5 g, 4,4′-dimethoxydiphenylamine, 0,084 g palladium acetate, then 0.130 g tri-tert-butylphosphonium tetrafluorborate and flushed thoroughly with nitrogen. The flask was then charged with 60 mL toluene and degassed. 2.7 g sodium tert-butoxide was then added to yield a dark purple mixture, which was refluxed overnight. Once the reaction was complete, it was cooled to near RT, 100 mL of water was added and the mixture was transferred to a separation funnel. 100 mL of toluene and 100 mL water was added to the funnel and mixed. The layers were then allowed to separate. The remaining aqueous layer was extracted with toluene. The combined organics were dried with magnesium sulfate and filtered over silica gel. The flask and silica gel were rinsed with toluene and the filtrates were rotovapped to get approximately 5 g of faint brown solids. Methanol was added and the solids were slurried in a 40° C. bath for 30 minutes, then cooled to RT, filtered, and rinsed with methanol. The resulting solids were dried via suction to obtain 3 g of off-white solids.

### Example 2

Synthesis of TPA-TPS, C₁₀₄H₈₈N₄O₈Si, MW 1549.92. A second tetrahedral hole transport material was prepared using the three-step synthesis described herein.

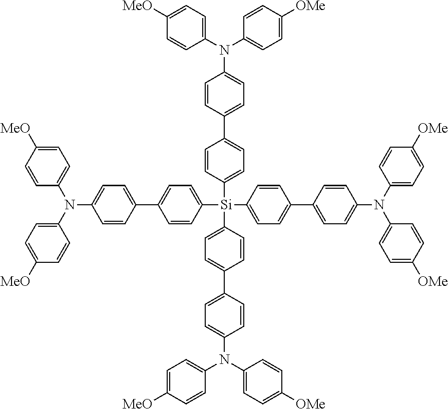 [SMILES: COc1ccc(N(c2ccc(OC)cc2)c2ccc(-c3ccc([Si](c4ccc(-c5ccc(N(c6ccc(OC)cc6)c6ccc(OC)cc6)cc5)cc4)(c4ccc(-c5ccc(N(c6ccc(OC)cc6)c6ccc(OC)cc6)cc5)cc4)c4ccc(-c5ccc(N(c6ccc(OC)cc6)c6ccc(OC)cc6)cc5)cc4)cc3)cc2)cc1]

A flask was charged with 7.0 potassium phosphate and 10 mL water, 100 mL toluene was added and the mixture degassed. The flask was then charged with 2.6 g tetrakis(4-bromophenyl) silane, 8.6 g, (4-(4,4,5,5-tetramethyl-(1,3,2)dioxaborolan-2-yl)-phenyl)-di-(4-methoxyhenyl)amine, 0.07 g palladium acetate, then 0.26 g 2-dicyclohexylphosphino-2′,6′-dimethoxybiphenyl, and an orange solution formed. The mixture was heated to reflux and refluxed overnight. Once the reaction was complete, it was cooled to near RT, 100 mL of water was added, the mixture was stirred for approximately 10 minutes, and transferred to a separation funnel. 100 mL of toluene and 100 mL water was added to the funnel and mixed. The layers were then allowed to separate. The aqueous layer was extracted twice with toluene. The combined organics were dried with magnesium sulfate and filtered over silica gel. The flask and silica gel were rinsed with toluene and the filtrates were rotovapped to get approximately 7.9 g of foamy yellow solids. The solids were dissolved in 25 mL tetrahydrofuran then poured slowly into a beaker of stirring methanol. The mixture was stirred 10 minutes, then pale yellow solids were filtered off and rinsed with methanol. The resulting solids were dried via suction to obtain 8.5 g of off-white solids and NMR was done for confirmation.

### Example 3

Synthesis of Si-spiro-MeOTAD analog. C₈₀H₆₈N₄O₈Si, MW 1241.50 g/mol. An analog of spiro-MeOTAD with a silicon center atom, rather than carbon, was prepared using the simplified three-step method disclosed herein.

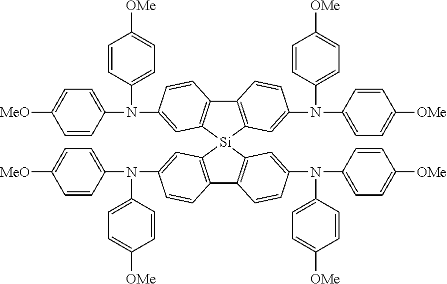 [SMILES: COc1ccc(N(c2ccc(OC)cc2)c2ccc3c(c2)[Si]2(c4cc(N(c5ccc(OC)cc5)c5ccc(OC)cc5)ccc4-3)c3cc(N(c4ccc(OC)cc4)c4ccc(OC)cc4)ccc3-c3ccc(N(c4ccc(OC)cc4)c4ccc(OC)cc4)cc32)cc1]

A 3-N 250 mL flask with stir bar, was set up and condenser with G1A, connected to Manifold with an inline oil bubbler, a rubber septum, and thermometer. This was then dried and flushed with nitrogen. The flask was charged with 2,2′-dibromo-N4,N4,N4′,N4′-tetrakis(4-methoxyphenyl)-[1,1′-biphenyl]-4,4′-diamine (3.8 g) and flushed with nitrogen. The flask was then charged with dry cyclohexane (90 mL) and dry tetrahydrofuran (10 mL). The white suspension was subsequently degassed with a gas dispersion tube and cooled to 5° C. using an ice water bath. 2.50 M of n-butyllithium in hexane (4.1 mL) was added to the reaction solution slowly via syringe over 10 minutes. The white suspension turned bright yellow and the temperature stayed near 5-6° C. The solids dissolved in to the solvents to form a slightly turbid yellow mixture. The mixture was stirred in the ice water bath for 60 minutes. No change in the appearance occurred. Consumption of the starting material was confirmed by TLC. Silicon(IV) chloride (0.30 mL) was added dropwise via syringe over 5 minutes. The yellow-orange solution turned bright yellow in color and became turbid. The ice bath was removed and the mixture stirred overnight. Product was confirmed via TLC and the mixture was then heated to reflux. Once complete, dry toluene was added (100 mL) and the mixture was stirred. Water (100 mL) was added and the mixture stirred for 10 minutes. The mixture was transferred the mixture to a separation funnel. Toluene (100 mL) and water (100 mL) were added and agitated. The aqueous layer was separated. The orange organic layer was washed with water (200 mL) and dried with magnesium sulfate (10 g) and filtered over Celite. A fine material was collected and rinsed with portions of toluene (100 mL) to get a clear orange solution. The solution was rotovapped to obtain orange-brown solids, 3.1 g. identity of result was confirmed by NMR. The solids were then dissolved in toluene (200 mL) then filtered over wet silica gel (100 g) under reduced pressure, and rinsed with toluene to remove unreacted material, then rinsed to obtain a bright yellow green solution as the filtrate. The mixture darkened upon standing; 3 drops hydrazine monohydrate (0.3 mL) was added to reduce any oxidized material. The resulting solution was rotovapped to obtain a bright yellow green glassy solids, and NMR was done for confirmation.

Column Chromatography using 3:1 Heptane/Ethyl Acetate. Filtrate was collected until yellow band reached the bottom, then further 200-mL fractions were collected until it came through. The combined fractions were rotovapped to obtain 0.8 g bright yellow glassy solid, confirmed by NMR. The solids were dissolved in tetrahydrofuran (8 mL), then added dropwise to stirring Methanol (100 mL). Tetrahydrofuran (2 mL) was used to complete the transfer. Bright yellow solids were filtered off, rinsing with a small portion of methanol, and dried by suction to obtain 0.6 g yellow powder, with a yield of approximately 20%.

### Example 4

A second synthesis of the Si-spiro-MeOTAD analog was performed. A 3-N 250 mL flask with stir bar, was set up and condenser with G1A, connected to Manifold with an inline oil bubbler, a rubber septum, and thermometer. This was then dried and flushed with nitrogen. The flask was charged with 2,2′-dibromo-N4,N4,N4′,N4′-tetrakis(4-methoxyphenyl)-[1,1′-biphenyl]-4,4′-diamine (3.8 g) and flushed with nitrogen. The flask was then charged with ether for form a white suspension. The white suspension was subsequently degassed with a gas dispersion tube. 4.2 mL of 2.50 M n-butyllithium in hexane was added to the reaction solution slowly via addition funnel. The white suspension turned to a slightly turbid yellow solution, with some particles suspended, and was stirred at RT for 2 hours. All solids dissolved within 30 minutes, and after 2 hours the solution appeared more turbid.

Solid triphenylphosphate (0.93 g) was added directly to the flask. The yellow solution immediately turned to cloudy yellow and was stirred overnight. A 1M HCl was prepared, into which potassium bromide (10.0 g) was dissolved. The KBr solution was added to the yellow suspension, and the mixture turned dark red during the addition. The resulting mixture was stirred for 1 h. A red solid was filtered off and rinsed water, then ether, and dried via suction to obtain 3.3 g red solids and the identity was confirmed by NMR. The red solids were dissolved in dichloromethane (100 mL), then washed with water (100 mL) in a sep, funnel. The aqueous layer was extracted with dichloromethane. The combined organics were dried with sodium sulfate (10 g) then filtered into a 500-mL 1 N flask. The filtrate was rotovapped to obtain a red solid. Ether (100 mL) was added and the mixture slurried by stirring overnight. The red solids were filtered and rinsed with ether, then dried by suction to obtain 1.7 g red solids. The solids were charged to a 500-mL flask with stir bar and dissolved in tetrahydrofuran (100 mL) and methanol (100 mL) to form a red solution. Bis(trifluoromethane)sulfonimide lithium salt (1.1 g) was dissolved in water (50 mL) and added dropwise to the flask. Some turbidity formed. The flask was fitted with a condenser and heated to reflux under nitrogen. The mixture was refluxed over the course of 3 days, then cooled to RT. It was then transferred to a sep funnel and water (200 mL), and ethyl acetate (200 mL) were added and the resulting combination mixed then allowed to separate fully. The organic layer was collected and rotovapped to obtain glassy red solids with a purified yield of 20%.

### Example 5

Synthesis of P⁺-Spiro-MeOTADBr⁻ intermediate, C₈₀H₆₈BrN₄O₈P, MW 1324.30, and P⁺-Spiro-MeOTAD bistriflimide product, C₈₂H₆₈F₆N₅O₁₂PS₂, MW 1524.54 g/mol.

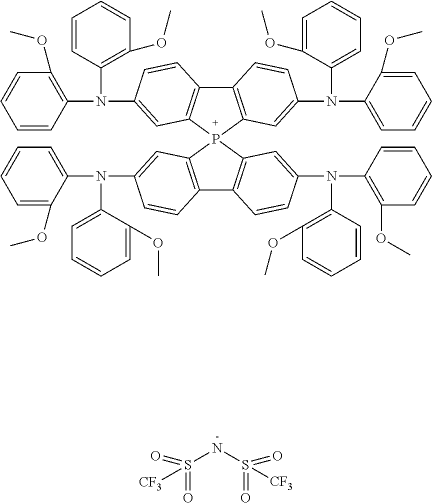

A 3-N 250 mL flask with stir bar was fitted with a condenser with GA, connected to manifold with an inline oil bubbler, a rubber septum, and low-temp alcohol thermometer. The flask with 2,2′-dibromo-N4,N4,N4′,N4′-tetrakis(4-methoxyphenyl)-[1,1′-biphenyl]-4,4′-diamine (3.8 g) and flushed thoroughly with nitrogen. The flask was then charged with dry ether (200 mL) to form a white suspension, then degassed with a gas dispersion tube. 2.50 M n-butyllithium in hexane (4.2 mL) was cautiously added to the reaction solution via addition. The white suspension turned to a slightly turbid yellow solution, with some particles suspended. The mixture was stirred at RT for 2 hours. All the solids dissolved within 30 minutes, and after 2 hours, the solution appeared more turbid.

Solid triphenylphosphate (0.93 g) was added directly to the flask and the yellow solution immediately turned to cloudy yellow. The resulting mixture was stirred overnight. A 1M HCl solution in water was prepared, then solid potassium bromide (10.0 g) was added and dissolved. The KBr solution was added to the yellow suspension, and the mixture turned dark red during the addition. This mixture was stirred for one hour. Subsequently, the red solid was filtered off, and rinsed with water, then ether and dried via suction to obtain 3.3 g red solids. The identity was confirmed via NMR. The red solids were dissolved in dichloromethane (100 mL), then washed with water in a sep funnel. The aqueous layer was extracted with dichloromethane. The combined organics were collected and dried with sodium sulfate (10 g) then filtered into a 500-ml 1 N flask. The filtrate was rotovapped to obtain a red solid. Ether (100 ml) was added, and the mixture was slurried by stirring overnight. The resulting red solids were filtered, rinsed with ether, and dried by suction to obtain 1.7 g red solids.

The solids were charged to a 500-mL flask with a stir bar and dissolved in tetrahydrofuran (100 mL) and methanol (100 mL) to form a red solution. Bis(trifluoromethane)sulfonimide lithium salt (1.1 g) was dissolved I water (50 mL) and cautiously added dropwise to the flask. Some turbidity formed. The flask was fitted with a condenser and heated to reflux under nitrogen. The mixture was refluxed for 3 days, then cooled to RT. It was then transferred to a sep funnel and water (200 mL) and ethyl acetate (200 mL) were added. The result was mixed then the layers were allowed to separate. The organic layer was collected and rotovapped to obtain glassy red solids. The yield of the PBr-Spiro-MeOTAD was 45%, and the yield of the final P⁺-Spiro-MeOTAD bistriflimide product was calculated to be 44%.

### Example 6

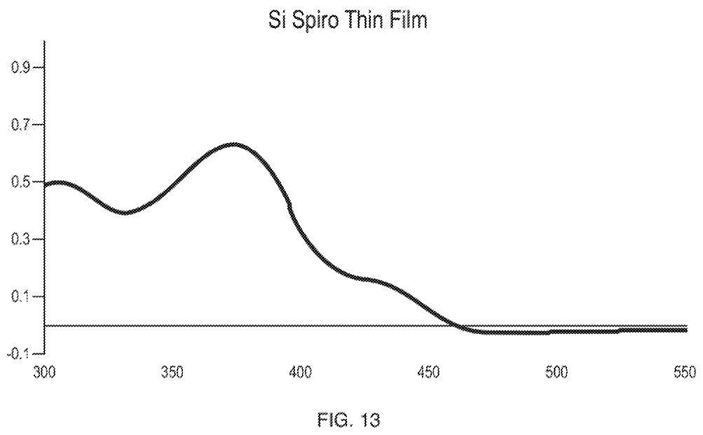

Calculation of Band Gap for Si-spiro-MeOTAD thin film. A thin film of Si-spiro-MeOTAD analog was coated on quartz and a UV-Vis spectrum was taken. The resulting spectrum is shown in FIG. 13. From this, the band gap was calculated to be 3.05 eV (2.70 eV).

### Example 7

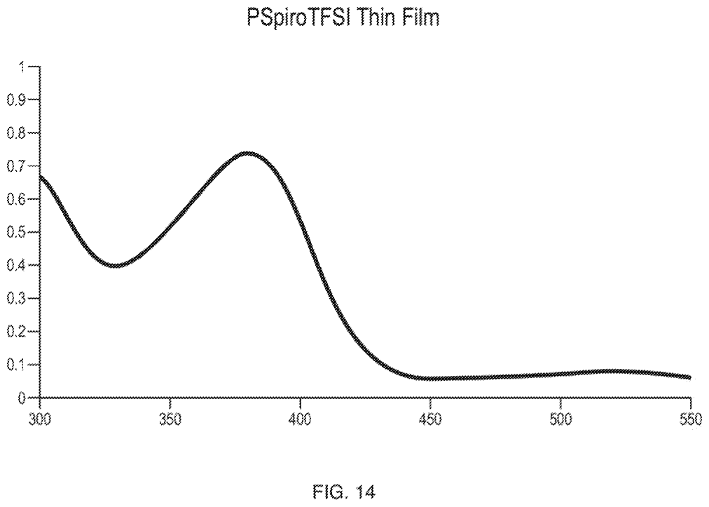

Calculation of Band Gap for P-spiro-MeOTAD bistriflimide. A thin film of P-spiro-MeOTAD bistriflimide was coated on quartz and a UV-Vis spectrum was taken. The resulting spectrum is shown in FIG. 14. The band gap was calculated to be 2.99 eV.

### Example 8

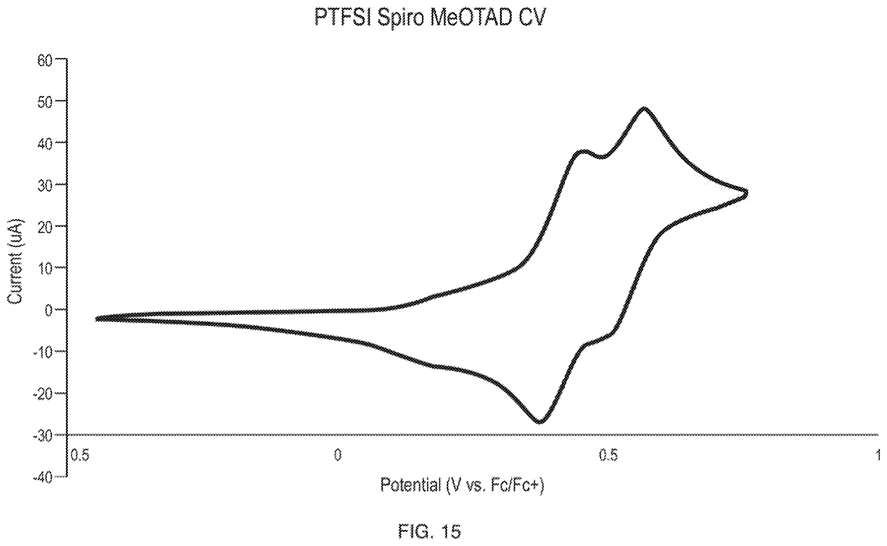

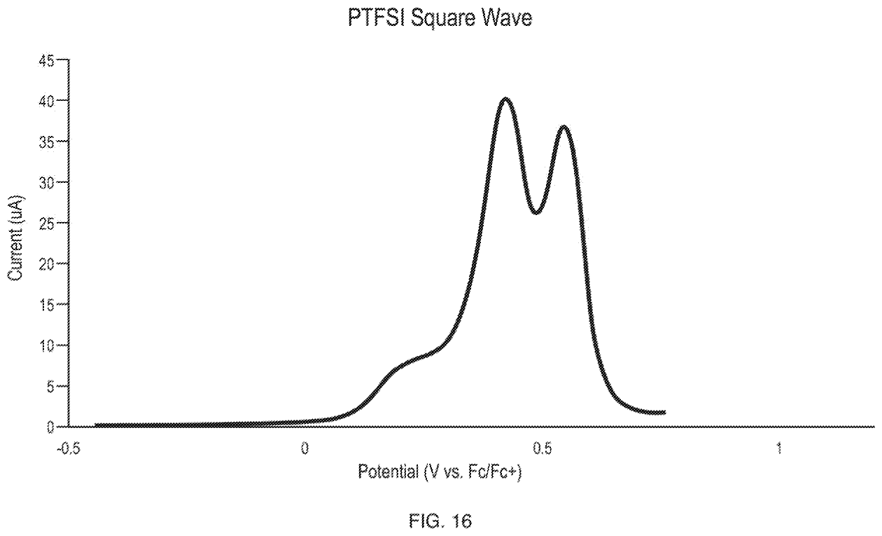

Voltammetry. Cyclic voltammetry and square wave voltammetry were performed on a sample of spiro-MeOTAD bistriflimide. The resulting voltammograms are shown in FIGS. 15 and 16, respectively. From the cyclic voltammetry experiment, E(HOMO) was determined to be −5.34 eV, E(LUMO) was determined to be −2.35 eV, and the band gap was then determined to be 2.99 eV.

The compounds, materials, methods and examples provided herein are not meant to limit the scope of the invention as set forth in the claims.

1. A compound of Formula I: 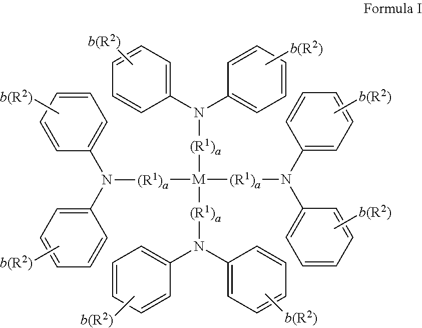
wherein:
M is selected from the group consisting of Si, Ge, B⁻ and P⁺, Sn and Pb;
R¹ is selected from the group consisting of arylene and heteroarylene, each R¹ is optionally substituted with one or more substituents R³, wherein R³ is selected from the group consisting of C₁ to C₈ alkyl, C₁ to C₈ alkoxy, aryl, alkylaryl and arylalkyl, or R³ is a bridging group that joins two adjacent R¹ groups to form a polycyclic aromatic group, and is selected from the group consisting of —(CR⁴R⁵)_{d}—, —O—, —SO₂— and —N(R⁶)—, wherein R⁴ and R⁵ are selected from the group consisting of H and C₁ to C₄ alkyl, d is 1 or 2, and R⁶ is selected from the group consisting of methyl, ethyl, and phenyl;
a is 2 or 3,
R² is selected from the group consisting of C₁ to C₈ alkoxy, CF₃, and N(R⁷)₂, wherein R⁷ is C₁ to C₄ alkyl;
b represents 1, 2, 3 or 4 R² groups per phenyl ring; and
when M is charged, the compound further includes a counterion;
with the proviso that when M is Si, R¹ is phenylene, and b represents 1 R² group, then a is not 2.

2. The compound of claim 1 wherein M is selected from the group consisting of Si, Ge, B⁻ and P⁺.

3. The compound of claim 2 wherein M is Si.

4. The compound of claim 1 wherein R₁ is selected from the group consisting of phenylene and thiophene.

5. (canceled)

6. The compound of claim 1 wherein two adjacent R¹ groups are joined by bridging group R³ to form a polycyclic aromatic group.

7. The compound of claim 1 wherein M is P⁺ and the counterion is selected from the group consisting of halide, bistriflimide, triflate, hexafluorophosphate and combinations thereof.

8. The compound of claim 1 wherein M is B⁻ and the counterion is an alkali metal cation.

9. The compound of claim 1 wherein R² is selected from the group consisting of C₁ to C₄ alkoxy and b is 1 or 2.

10. The compound of claim 9 wherein b is 1 and R² is selected from the group consisting of para-methoxy and ortho-methoxy.

11. The compound of claim 1 selected from the group consisting of:

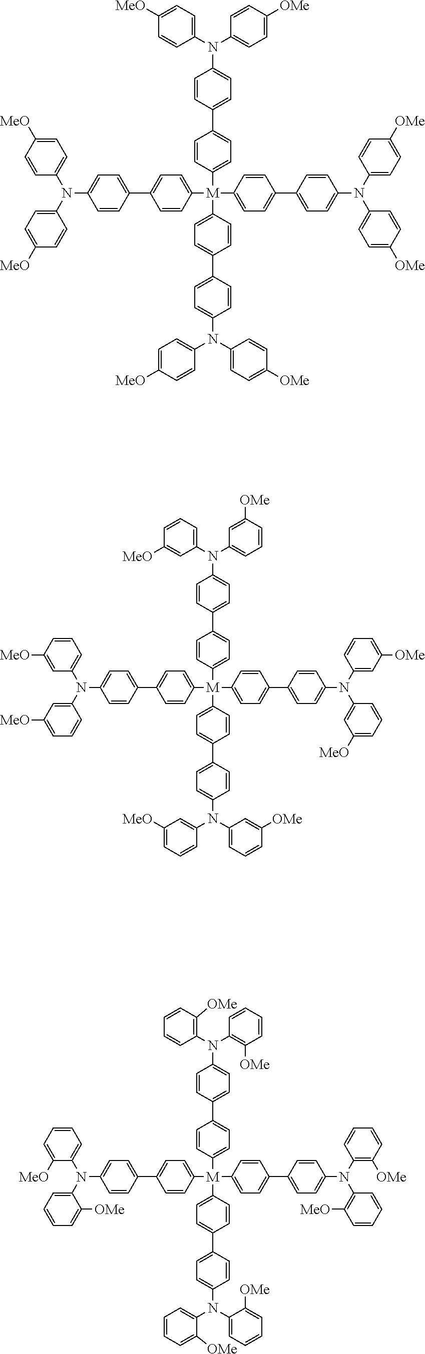

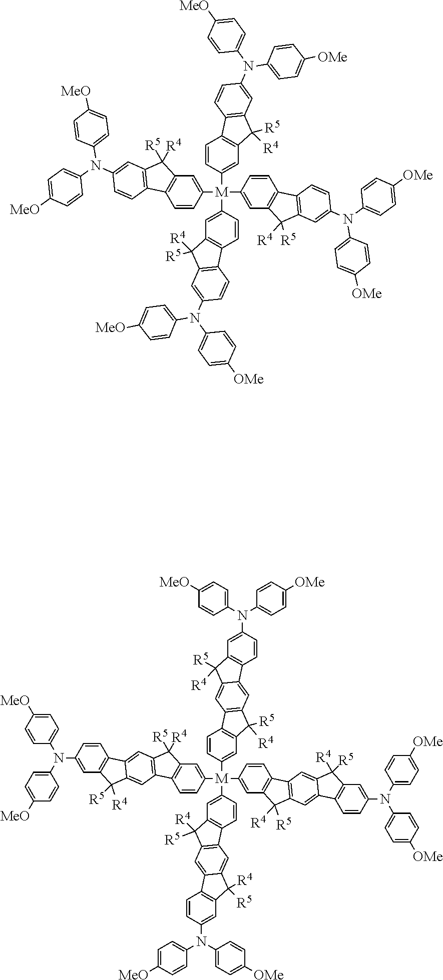

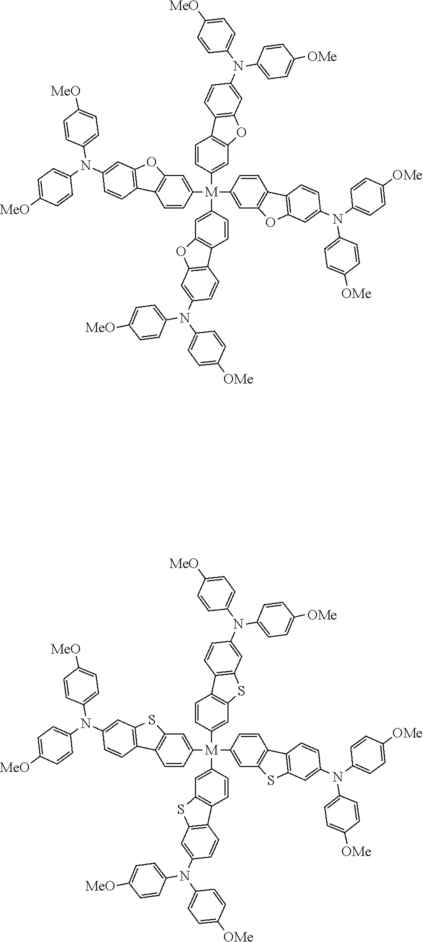

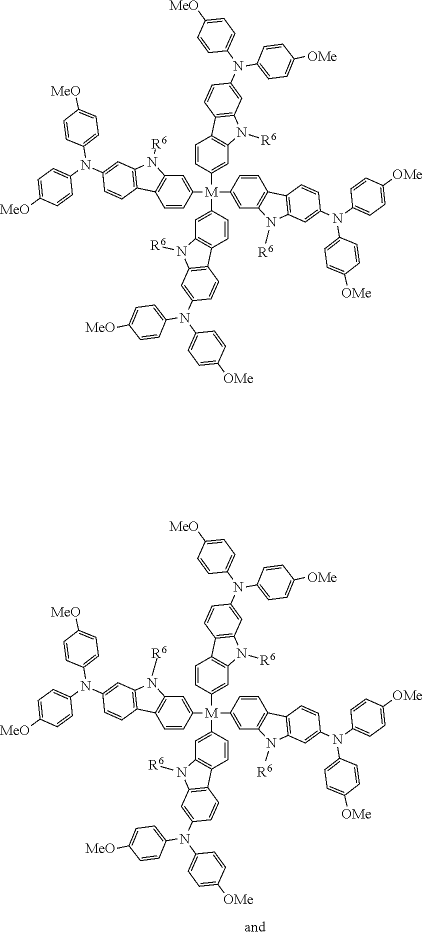

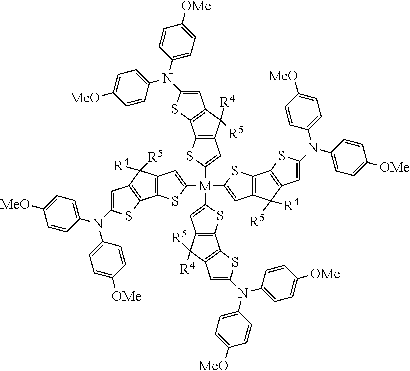

12. The compound of claim 11 selected from the group consisting of

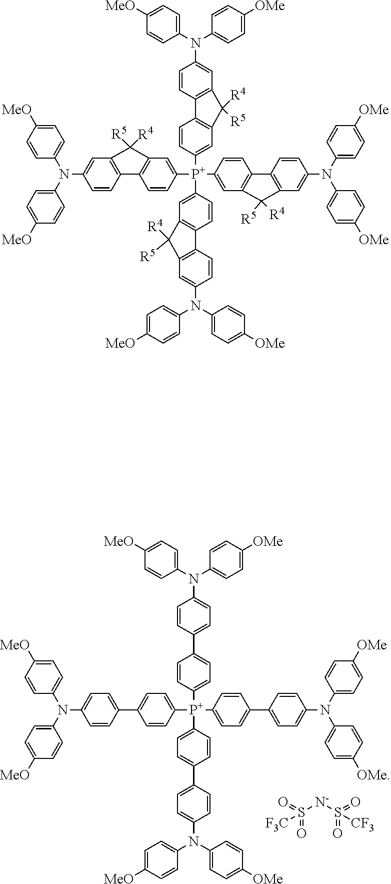

13. A compound of Formula II: 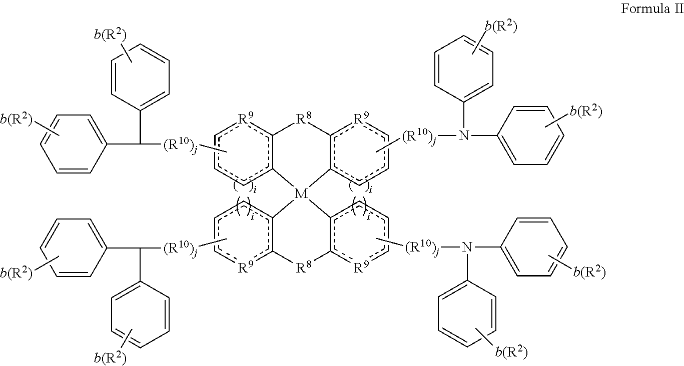
wherein
M is selected from the group consisting of Si, Ge, B⁻, P⁺, Sn and Pb;
R⁸ is selected from the group consisting of —(CR⁴R⁵)—, —S—, —O—, —SO₂— and —N(R⁶)—, wherein e is 0 or 1, R⁴ and R⁵ are selected from the group consisting of H and C₁ to C₄ alkyl, and R⁶ is selected from the group consisting of methyl, ethyl, and phenyl;
R⁹ is selected from the group consisting of —CH— and —S—;
i is 0 or 1;
R¹⁰ is selected from the group consisting of phenylene and thiophene;
j is 0, 1 or 2;
R₂ is selected from the group consisting of C₁ to C₈ alkoxy, CF₃, and N(R⁷)₂, wherein R⁷ is C₁ to C₄ alkyl;
b represents 1, 2, 3 or 4 substituents per ring; and
when M is charged, the compound further includes a counterion,
with the proviso that when i is 0, and R² is methoxy in the para position, M is not Si.

14. The compound of claim 13 represented by Formula IIa: 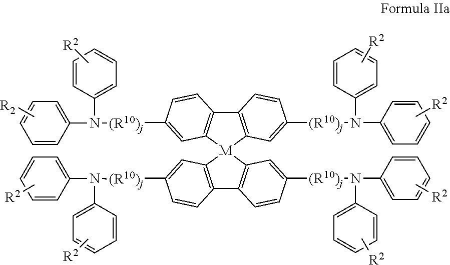
wherein
M is selected from the group consisting of Si, Ge, B⁺ and P⁻;
R¹⁰ is selected from phenylene and thiophene;
j is 0, 1 or 2;
R² is selected from the group consisting of C₁ to C₄ alkoxy; and
when M is charged, the compound further includes a counterion.

15. The compound of claim 14 selected from the group consisting of

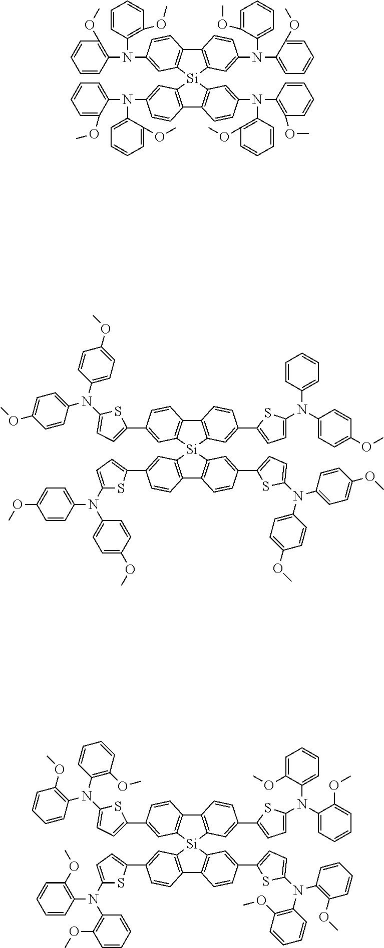

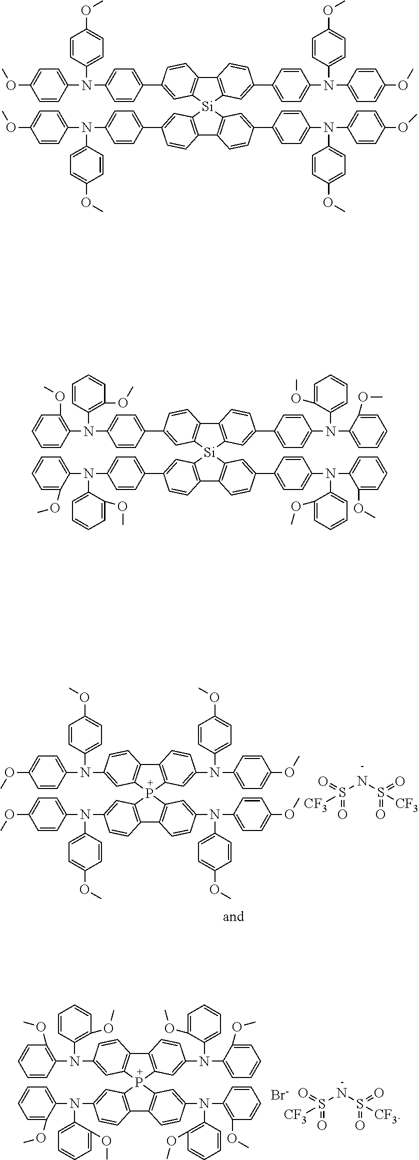

16. The compound of claim 13 represented by Formula IIb: 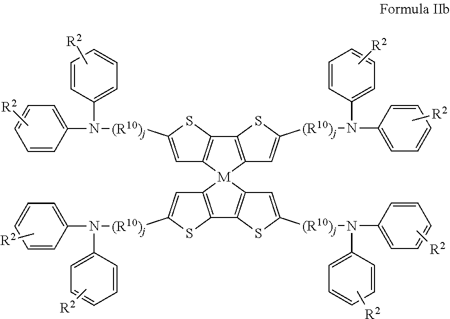
wherein
M is selected from the group consisting of Si, Ge, B⁺ and P⁻;
R¹⁰ is selected from phenylene and thiophene;
j is 0, 1 or 2;
R² is selected from the group consisting of C₁ to C₄ alkoxy; and
when M is charged, the compound further includes a counterion.

17. The compound of claim 16 selected from the group consisting of

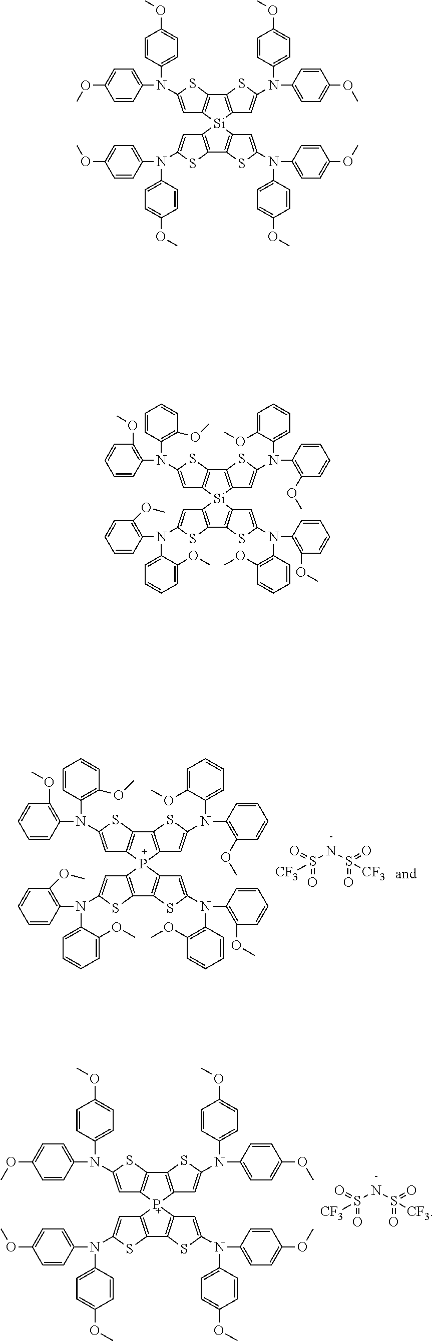

18. The compound of claim 13 represented by Formula IIc 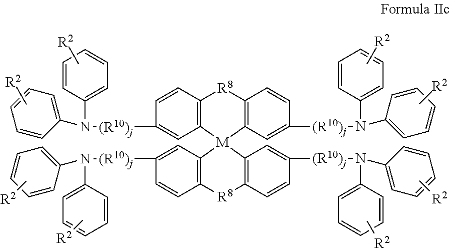
wherein
M is selected from the group consisting of Si, Ge, B⁺ and P⁻;
R⁸ is selected from the group consisting of —S—, —O—, —SO₂— and —N(R)—, wherein R⁶ is selected from the group consisting of methyl, ethyl, and phenyl;
R¹⁰ is selected from phenylene and thiophene;
j is 0, 1 or 2;
R² is selected from the group consisting of C₁ to C₄ alkoxy; and
when M is charged, the compound further includes a counterion.

19. The compound of claim 18 selected from the group consisting of 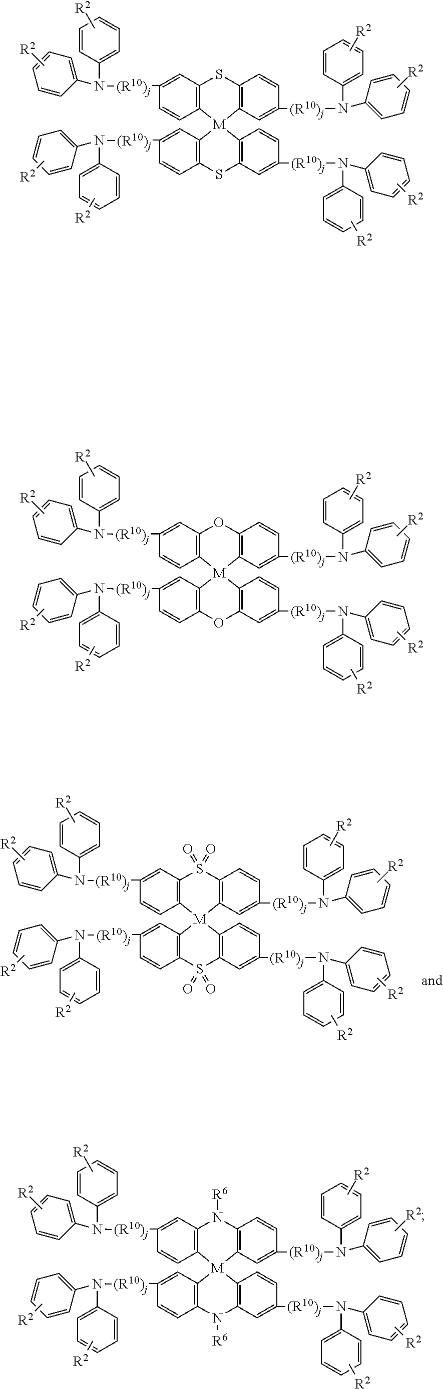
wherein
M is selected from the group consisting of Si, Ge, B⁺ and P⁻;
R² is selected from para-methoxy and ortho-methoxy;
R⁶ is selected from the group consisting of methyl, ethyl, and phenyl;
R¹⁰ is selected from phenylene and thiophene;
j is 0 or 1; and
when M is charged, the compound further includes a counterion.

20. A compound of Formula III 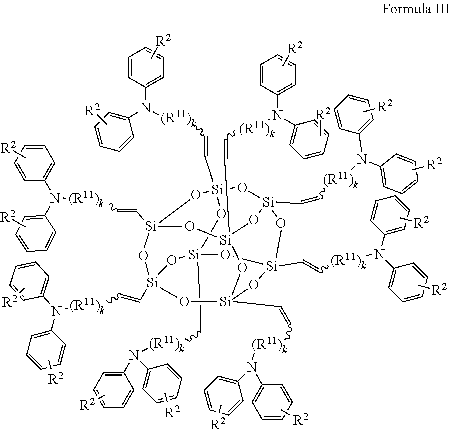
wherein [symbol]
indicates that the bond can be cis or trans;
R¹¹ is C₆ to C₁₃ arylene;
k is 1 or 2; and
R² is selected from the group consisting of C₁ to C₈ alkoxy, CF₃, and N(R⁷)₂, wherein R⁷ is C₁ to C₄ alkyl.

21. The compound of claim 20 wherein R¹¹ is selected from the group consisting of phenylene and fluorenylidene.

22. The compound of claim 21 wherein R¹¹ is selected from the group consisting of 1,4-phenylene and 2,7-9H-fluorenylidene.

23. A device comprising a cathode, a hole transport layer, a light absorbing material, an electron transport layer and an anode,
wherein the hole transport layer comprises a compound selected from the group consisting of Formula I, Formula Ia, Formula II and Formula III.

24. The device of claim 23 wherein the hole transport layer is a thin film.

25. The device of claim 24 wherein the thin film is a printed film.

26. The device of claim 23 wherein the light absorbing material is a perovskite material.

27. The device of claim 26 wherein the device is a solar cell.

28. A compound of Formula Ia: 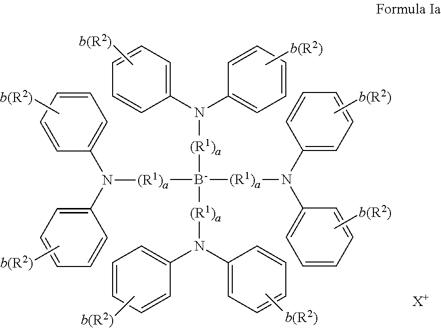
wherein:
R¹ is selected from the group consisting of arylene and heteroarylene, each R¹ is optionally substituted with one or more substituents R³, wherein R³ is selected from the group consisting of C₁ to C₈ alkyl, C₁ to C₈ alkoxy, aryl, alkylaryl and arylalkyl, or R³ is a bridging group that joins two adjacent R¹ groups to form a polycyclic aromatic group, and is selected from the group consisting of —(CR⁴R⁵)_{d}—, —O—, —SO₂— and —N(R⁶)—, wherein R⁴ and R⁵ are selected from the group consisting of H and C₁ to C₄ alkyl, d is 1 or 2, and R⁶ is selected from the group consisting of methyl, ethyl, and phenyl;
a is 1, 2 or 3,
R² is selected from the group consisting of C₁ to C₈ alkoxy, CF₃, and N(R⁷)₂, wherein R⁷ is C₁ to C₄ alkyl;
b represents 1, 2, 3 or 4 R² groups per phenyl ring; and
X⁺ is a counterion.

29. The compound of claim 28 wherein R₁ is selected from the group consisting of phenylene and thiophene.

30. The compound of claim 28 wherein X⁺ is an alkali metal cation.

31. The compound of claim 28 wherein R² is selected from the group consisting of C₁ to C₄ alkoxy and b is 1 or 2.

32. The compound of claim 31 wherein b is 1 and R² is selected from the group consisting of para-methoxy and ortho-methoxy.

33. The compound of claim 28 selected from the group consisting of: 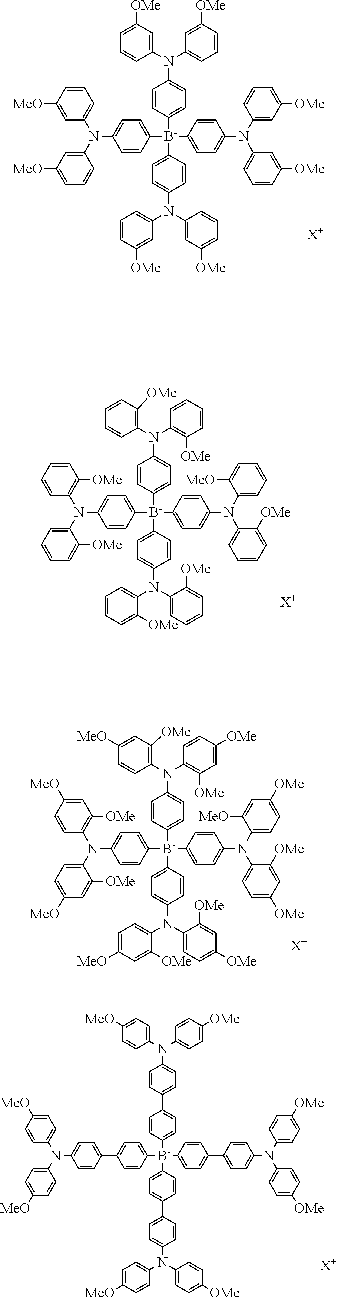 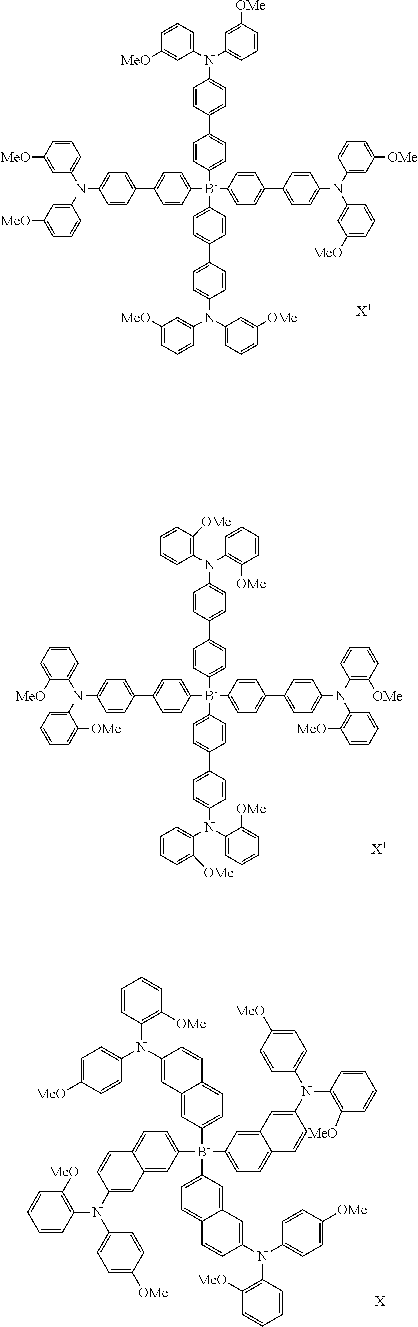 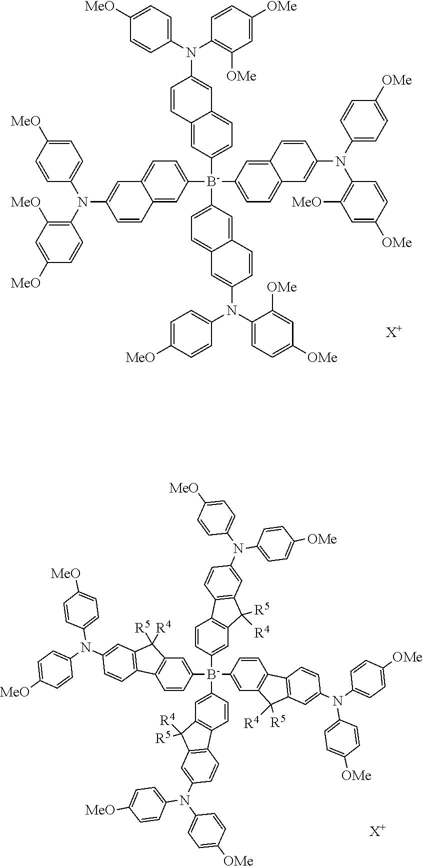 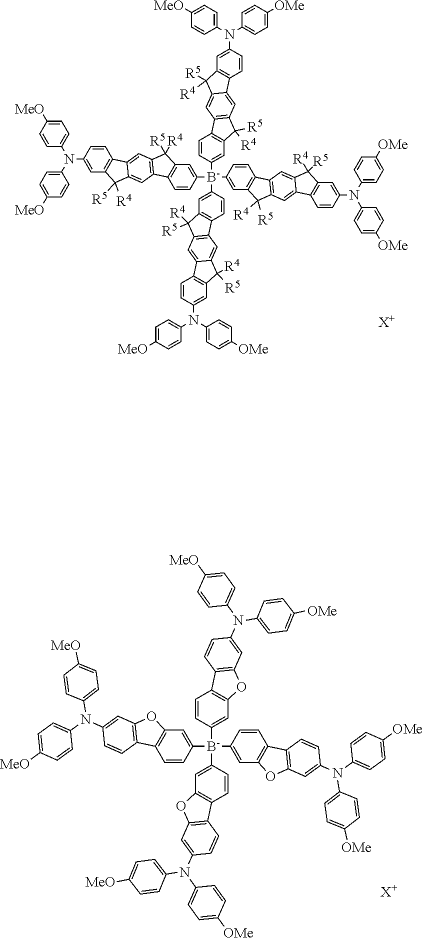 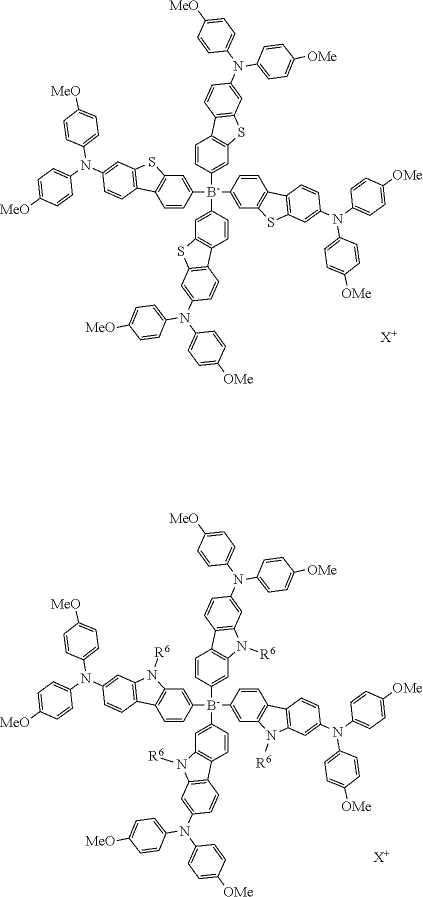 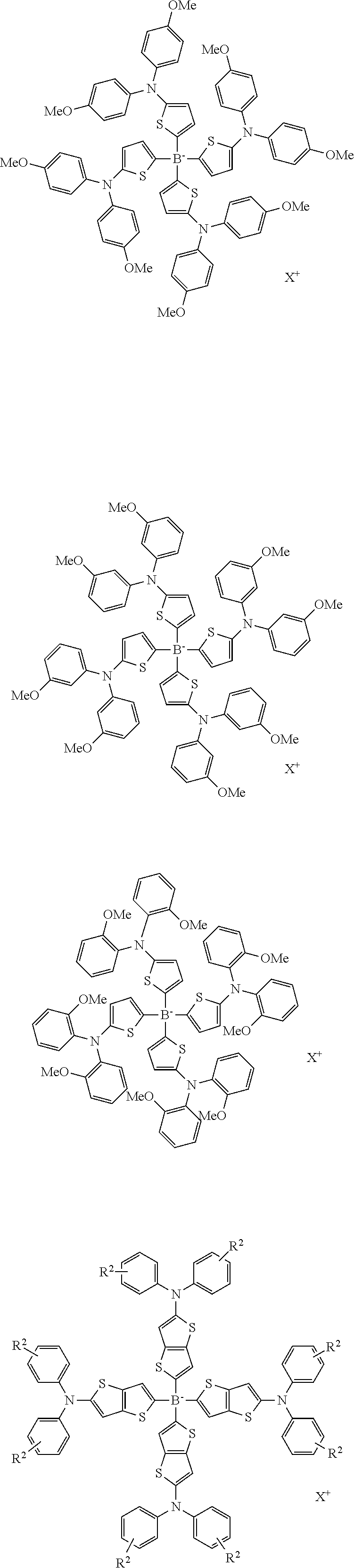 [chemical structure]
